(19) United States
(12) Patent Application Publication
(10) Pub. No.: US 2023/0400508 A1
(43) Pub. Date: Dec. 14, 2023

(54) SUBSTRATE PROCESSING SYSTEM TOOLS FOR MONITORING, ASSESSING AND RESPONDING BASED ON HEALTH INCLUDING SENSOR MAPPING AND TRIGGERED DATALOGGING

(71) Applicant: LAM RESEARCH CORPORATION, Fremont, CA (US)

(72) Inventors: Bridget Hill FREESE, Mountain View, CA (US); Scott BALDWIN, Reston, VA (US); Justin TANG, Clovis, CA (US); Raymond CHAU, San Ramon, CA (US); Thor Andreas RAABE, Tampa, FL (US); Robert J. STEGER, Union City, CA (US); Lin ZHU, Sunnyvale, CA (US)

(21) Appl. No.: 18/034,834

(22) PCT Filed: Nov. 3, 2021
(86) PCT No.: PCT/US2021/072198

§ 371 Date: May 1, 2023

Related U.S. Application Data
(60) Provisional application No. 63/112,386, filed on Nov. 11, 2020.

(51) Int. Cl. G01R 31/28; G05B 23/02; H01L 21/67

(52) U.S. Cl. CPC G01R 31/2894; G05B 23/0235; G05B 23/0283; H01L 21/67288; H01L 21/67276

(57) ABSTRACT

A health monitoring, assessing and response system includes an interface and a controller. The interface is configured to receive a signal from a sensor disposed in a substrate processing system. The controller includes a health index module. The health index module is configured to perform an algorithm including: obtaining a window and a boundary threshold; monitoring the signal output from the sensor; determining whether the signal has crossed the boundary threshold; updating a health index component, where the health index component is a binary value and transitioned between HIGH and LOW values in response to the signal crossing the boundary threshold; and generating a health index value based on the health index component and decreasing the health index value from 100% to 0% over a duration of at least the window. The controller is configured to perform a countermeasure based on the health index value.

### CROSS-REFERENCE TO RELATED APPLICATIONS

This application claims the benefit of U.S. Provisional Application No. 63/112,386, filed on Nov. 11, 2020. The entire disclosure of the above application is incorporated herein by reference.

### FIELD

The present disclosure relates to systems for assessing health of substrate processing system tools.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Machines used in industrial manufacturing processes are often monitored by collecting data from sensors monitoring parameters such as flow rates, pressures, rotational speeds, etc. Alarm limits are often applied to the parameters to detect machine operating conditions that are considered unacceptable. Alarm limits may be used to prevent injury, damage to machinery, and/or manufacturing defects. When one of the monitored parameters exceeds an alarm limit, an alarm may be generated and operation of the machine may be halted. Time lag exists from when the alarm is generated to when operators and/or maintenance personnel become aware of and are able to respond to the alarm and address the unacceptable operating condition. In some cases, additional manufacturing downtime is lost to assess and understand the cause of the alarm. Further delay occurs in assembling the necessary personnel, components, materials, equipment etc. needed to perform corrective action and bring the machine back into a proper operating condition. The downtime of the machine reduces availability of the machine and productivity. Additionally, the unacceptable operating condition may cause irreversible defects, which further increases associated economic loss.

### SUMMARY

According to certain embodiments, the present disclosure discloses a health monitoring, assessing and response system is provided and includes an interface and a controller. The interface is configured to receive a first signal from a first sensor disposed in a substrate processing system. The controller includes a health index module. The health index module is configured to perform an algorithm including: obtaining a window and a boundary threshold; monitoring the first signal output from the first sensor; determining whether the first signal has crossed the boundary threshold; updating a health index component, where the health index component is a binary value and transitioned between HIGH and LOW values in response to the first signal crossing the boundary threshold; and generating a first health index value based on the health index component and decreasing the first health index value from 100% to 0% over a duration of at least the window. The controller is configured to perform a countermeasure based on the first health index value.

In some embodiments the health index module is configured to generate the first health index value as an average of updated values of the health index component over a duration of the window. The updated values of the health index component are determined during respective iterations of the algorithm.

In some embodiments, the health index module is configured to generate an updated health index value during each iteration of the algorithm. The controller is configured to perform the countermeasure based on the updated health index values.

In some embodiments, the health index module is configured to select the window and the boundary threshold such that the health index value decreases to 0% prior to or when the first signal reaches an alarm limit.

In some embodiments, the health index module is configured to adaptively adjust the boundary threshold during iterations of the algorithm to extend an amount of time during which the health index value decreases from 100% to 0%.

In some embodiments, the health index module is configured to adaptively adjust the boundary threshold during iterations of the algorithm such that the health index value decreases to 0% prior to or when the first signal equals an alarm limit.

In some embodiments, the health index module is configured to: implement a finite impulse response filter to determine a degradation rate of the first signal; and adjust the boundary threshold based on the degradation rate.

In some embodiments, the health index module is configured to determine the boundary threshold based on a degradation rate of the first signal, a duration of the window, and an alarm limit.

In some embodiments, the health index module is configured to: estimate a degradation rate of the first signal as a sum of weighted changes in the first signal; and determine the boundary threshold based on the estimated degradation rate.

In some embodiments, the controller is configured to perform the countermeasure in response to at least one of the first health index value decreasing, reaching a predetermined level or being within a predetermined range.

In some embodiments, the interface is configured to receive N signals from N sensors disposed in the substrate processing system, where N is greater than or equal to two, where the N signals include the first signal, and where the N sensors include the first sensor. The health index module is configured to: monitor the N signals output respectively from the N sensors; assess the N signals to determine a plurality of health index values including the first health index value; and aggregate the plurality of health index values to determine a system health index value. The controller is configured to perform the countermeasure in response to at least one of the system health index value decreasing, reaching a predetermined level or being within a predetermined range.

According to certain embodiments, the present disclosure discloses a health monitoring, assessing and response system that includes an interface and a controller. The interface is configured to receive data from N sensors disposed in a substrate processing system, where N is greater than or equal to two. The controller includes a health index module configured to: receive sets of data output respectively from the N sensors; assess the sets of received data to determine a plurality of health index values; and aggregate the plurality of health index values to determine a system health index value. The controller is configured to perform a countermeasure in response to at least one of the system health index value decreasing, reaching a predetermined level or being within a predetermined range.

According to certain embodiments, the present disclosure discloses a health monitoring, assessing and response system, which includes an interface and a controller. The interface is configured to receive data from N sensors disposed in a substrate processing system, where N is greater than or equal to two. The controller includes a health index module. The health index module is configured to: receive sets of data output respectively from the sensors; assess the sets of data to determine a plurality of health index values; aggregate the set of health index values to determine a system health index value; and determine whether the system health index value is outside a predetermined range. The controller is configured to perform a countermeasure in response to the system health index value being outside the predetermined range.

In some embodiments, the health index module is configured to determine second order polynomials respectively for the sets of data; and determine the plurality of health index values based on coefficients of the second order polynomials. In some embodiments, the health index module is configured to: compare the coefficients to a statistical distribution; and determine the plurality of health index values based on results of the comparison of the coefficients to the statistical distribution.

In some embodiments, the health index module is configured to: determine distributions of the coefficients; compare the distributions to health index boundaries; and determine the plurality of health index values based on results of comparing the distributions to the health index boundaries. In some embodiments, the health index module is configured to determine the system health index value based on a hierarchical structuring of health index calculations corresponding to at least one of a physical or functional decomposition of the substrate processing system.

In some embodiments, the health index module is configured to implement an aggregation algorithm and use Boolean operations corresponding to redundancy or lack of redundancy when determining the plurality of health index values and the system health index value. In some embodiments, the health index module is configured to select a minimum health index value of at least one of a hierarchical level or a sub-system level of the substrate processing system when generating the system health index value.

In some embodiments, each of the plurality of health index values and the system health index value is between 0-100%. In some embodiments, the controller is configured to define an event of the substrate processing system, indicated based on the system health index value as being abnormal, but within an acceptable range such that the controller refrains from generating an alarm or stopping operation of the substrate processing system. In some embodiments, the health index module is configured to generate the plurality of health index values based on N respective sets of events of the substrate processing system as detected by the N sensors.

In some embodiments, the health index module is configured to generate the plurality of health index values based on whether the N respective sets of events fall within defined normal operating conditions. In some embodiments, the health index module is configured to: use acquired data from an analog sensor over a time period defined by determined states of the substrate processing system; use a mathematical model to compute a secondary value characteristic of substrate processing system operation during the time period; and generate the system health index value based on the secondary value.

In some embodiments, the health index module is configured to scale the system health index value between a defined boundary level and an alarm level to indicate a severity of an operating condition beyond the boundary level. In some embodiments, the health index module uses non-linear scaling.

In some embodiments, the controller includes a sensor mapping module configured to display at least a portion of the substrate processing system and information associated with the N sensors. In some embodiments, the sensor mapping module is configured to display sensor identifiers, sensor states, and the N health index values over the at least a portion of the substrate processing system.

In some embodiments, the controller includes a sensor mapping module configured to display the plurality of health index values in a hierarchical format. In some embodiments, the sensor mapping module is configured to indicate physical locations of the N sensors in the substrate processing system.

In some embodiments, the sensor mapping module is configured to selectively, based on at least one of a system operator input or a received instruction, display one or more of the plurality of health index values for a selected hierarchical level of the substrate processing system. In some embodiments, the sensor mapping module is configured to display historical health index values for the N sensors.

In some embodiments, the sensor mapping module is configured to, based on at least one of a system operator input or a received instruction, display an aggregation level of plurality of health index values. In some embodiments, the health index module is configured to: determine normal operating boundaries based on operating the substrate processing system in a normal state for a selected period of time; and detect a potential issue or fault based on the normal operating boundaries.

In some embodiments, the health index module is configured to use time intervals between defined operations of the substrate processing system to a basis for determining the plurality of health index values. In some embodiments, the health index module is configured to use a mathematical module based on conditions to reduce the sets of data to N values based on which of the plurality of health index values are calculated. In some embodiments, the health index module is configured to determine the plurality of health index values periodically and based on one or more detected events of the substrate processing system as detected by the N sensors.

In some embodiments, the health index module is configured to determine the plurality of health index values periodically and based on one or more detected events. In some embodiments, the health index module is configured to determine the plurality of health index values based on a degree to which operation of the substrate processing system approaches an alarm limit.

In some embodiments, the health index module is configured to determine the plurality of health index values based on N boundaries located respectively between N normal operation ranges and N alarm limits. In some embodiments, the controller includes a datalogging module, where the datalogging module is configured to collect and store data from the N sensors based on instructions from the health index module.

In some embodiments, the datalogging module is configured to, based on at least one of the N health index values or rates of change of output values of the N sensors, initiate data collection from the N sensors or a subset of the N sensors. In some embodiments, the datalogging module is configured to, based on at least one of the plurality of health index values or rates of change of output values of the N sensors, increase a data sampling rate and collect data from the N sensors at the increased data rate.

In some embodiments, the health index module is configured to: detect degradation in the substrate processing system based on the system health index value; and collect additional data to determine a cause of the degradation. In some embodiments, the health monitoring, assessing and response system further includes the N sensors.

According to certain embodiments, the present disclosure also discloses a sensor mapping system that includes N sensors, an interface and a controller. The plurality of sensors are configured to detect respective parameters of a substrate processing system, where N is greater than or equal to two. The interface is configured to receive data from the N sensors. The controller includes a sensor mapping module. The sensor mapping module is configured to: receive instructions to display sensor information for the N sensors; receive N sets of data output respectively from the N sensors; and display locations of the N sensors along with the sensor information over a view of at least a portion of the substrate processing system.

In some embodiments, the sensor information includes at least one of a current sensor value, a historical aggregate value, a health index value, a part number, or a serial number. In some embodiments, the sensor mapping module is configured to display states of the N sensors over the view of the at least a portion of the substrate processing system.

In some embodiments, the controller further includes a health index module configured to generate a plurality of health index values respectively for the N sensors. The sensor mapping module is configured to display the plurality of health index values over the view of the at least a portion of the substrate processing system. In some embodiments, the sensor mapping module is configured to receive instructions from the health index module, where the instructions include selection of the N sensors from a set of M sensors, where M is greater than N.

In some embodiments, the sensor mapping module is configured to: receive at least one of a system operator input or an instruction signal; and based on the at least one of the system operator input or the instruction signal, plot data received from one or more of the N sensors. In some embodiments, the sensor mapping module is configured to: receive an input to display a plot of data for one of the N sensors; and display a graph including plotting data from the one of the N sensors, where the graph is shown on a same screen as the view of the at least the portion of the substrate processing system.

In some embodiments, the sensor mapping module is configured to, based on a received input, change at least one of a screen level or a displayed hierarchical level of the substrate processing system. In some embodiments, the sensor mapping module is configured to, based on an input, display sensor information for M sensors of the substrate processing system rather than the sensor information for the N sensors, where M is greater than or equal to 2. In some embodiments, the M sensors are exclusive of the N sensors. In some embodiments, the M sensors include one or more of the N sensors.

According to certain embodiments, the present disclosure also discloses a datalogging system. The datalogging system includes N sensors, an interface and a controller. The N sensors are configured to detect respective parameters of a substrate processing system, where N is greater than or equal to two. The interface is configured to receive data from the N sensors. The controller includes a datalogging module. The datalogging module is configured to: receive instructions to select the N sensors and trigger information; monitor at least one of the N sensors or other sensors and detect one or more trigger events identified by the trigger information; and data log outputs of the N sensors in response to detecting the one or more trigger events to provide logged data. The controller is configured to analyze the logged data and based on result of analyzing the logged data, performing a countermeasure.

In some embodiments, the datalogging module is configured to: receive instructions from a health index module, where the instructions include a selected set of sensors and triggers; and based on the triggers, log data from the selected set of sensors. In some embodiments, the selected set of sensors includes one or more of the N sensors. In some embodiments, the selected set of sensors does not include the N sensors.

In some embodiments, the datalogging module is configured to perform datalogging based on at least one of triggers, thresholds or conditions. The controller includes a health index module configured to: classify whether one or more operations of the substrate processing system occurred inside or outside of defined normal operating conditions; generate a plurality of health index values based on the classifying; and perform the countermeasure based on an aggregation of the plurality of health index values.

In some embodiments, the datalogging module is configured to: buffer data prior to the one or more trigger events; and store data for a set time period prior to the one or more trigger events. In some embodiments, the datalogging module is configured to log data for the N sensors based on trigger events associated with one or more other sensors.

In some embodiments, the datalogging module is configured to log data for the N sensors based on a detected one or more conditions of the substrate processing system. In some embodiments, the datalogging module is configured to capture intermittent events by recording data output from the N sensors for a set time period each time a triggering event occurs.

Further areas of applicability of the present disclosure will become apparent from the detailed description, the claims and the drawings. The detailed description and specific examples are intended for purposes of illustration only and are not intended to limit the scope of the present disclosure.

### BRIEF DESCRIPTION OF THE DRAWINGS

The present disclosure will become more fully understood from the detailed description and the accompanying drawings, wherein:

FIG. 1 is a functional block diagram of an example portion of a health monitoring, assessing and responding (HMAR) system according to certain embodiments of the present disclosure;

FIG. 2 is another example portion of the HMAR system including a controller and sensors according to certain embodiments of the present disclosure;

FIG. 3 is an example two-dimensional sensor information and health index (HI) reporting screen according to certain embodiments of the present disclosure;

FIG. 4 is an example three-dimensional sensor information and HI reporting screen according to certain embodiments of the present disclosure;

FIG. 5 illustrates an example process for obtaining HI values according to certain embodiments of the present disclosure;

FIG. 6 is an example parameter data plot including a second order polynomial best-fit curve according to certain embodiments of the present disclosure;

FIG. 7 is an example coefficient distribution plot for a coefficient of the second order polynomial best-fit curve of FIG. 6;

FIG. 8 is an example plot of a parameter distribution, a HI boundary and a hard limit according to certain embodiments of the present disclosure;

FIG. 9 is an example plot of the parameter distribution of FIG. 8 shifted relative to the HI boundary and the hard limit;

FIG. 10 is an example standard deviation expansion plot corresponding to the parameter distribution and relative to the HI boundary and the hard limit;

FIG. 11 is an example average parameter distribution plot according to certain embodiments of the present disclosure;

FIG. 12 is an example exponential factor distribution plot according to certain embodiments of the present disclosure;

FIG. 13 in an example hierarchical HI diagram screen of a graphical user interface according to certain embodiments of the present disclosure;

FIG. 14 illustrates a sensor information and HI reporting method according to certain embodiments of the present disclosure;

FIG. 15 illustrates a datalogging method according to certain embodiments of the present disclosure;

FIG. 16 is an example HI simulation graph illustrating linear decreasing degradation of a sensor signal according to certain embodiments of the present disclosure;

FIG. 17 is an example HI simulation graph illustrating linear increasing degradation of a sensor signal according to certain embodiments of the present disclosure;

FIG. 18 is an example HI simulation graph illustrating linear increasing degradation of a sensor signal with the introduction of noise according to certain embodiments of the present disclosure;

FIG. 19 is an example HI simulation graph including sampled points illustrating linear increasing degradation of a sensor signal with introduction of noise according to certain embodiments of the present disclosure;

FIG. 20 is an example HI simulation graph illustrating linear decreasing degradation of a sensor signal with introduction of noise and an adaptive boundary threshold according to certain embodiments of the present disclosure; and

FIG. 21 is another example process for obtaining HI values according to certain embodiments of the present disclosure.

In the drawings, reference numbers may be reused to identify similar and/or identical elements.

### DETAILED DESCRIPTION

A tool of a substrate processing system may include a load port module (LPM), an equipment front end module (EFEM), an airlock, a vacuum transfer module (VTM), and robots for transfer of substrates to and from chambers of substrate processing stations. The LPM, EFEM, airlock, VTM and robots could have numerous sensors such as temperature sensors, optical sensors (cameras), pressure sensors, relative humidity sensors, oxygen sensors, rocker valve sensors, vibration sensors, current and voltage sensors, etc. The sensors may be monitored to check states of various devices and run basic health check routines, such as leakby checks, which are done when the tool is idle. A leakby check may refer to a check of an amount of leak of a fluid through an interface and/or seal between components. Some of these types of checks are performed outside of normal processing conditions, such as when the corresponding processing system is idle and thus do not necessarily reflect the states of the system during processing. Some of the checks are performed infrequently and can delay a process from being performed. A system operator may be unable to determine that hardware degradation has occurred until subpar process results occur, which is especially true if the checks are performed infrequently.

When an improper operating condition exists with one of the modules, airlock robots, etc. of the tool, the tool may need to be shut down and processing time is lost. Due to the numerous sensors, complexity of the tool, and the interrelationships between features of the tool, it can be difficult to identify, locate and determine what is causing an alarm condition, which leads to extended periods of downtime. The alarm condition may be a direct or indirect result of an issue. When indirect, determination of the cause of the alarm condition can be more difficult to determine.

In some instances, a diagnostic tool may plot parameters of one or more sensors versus time on a user interface. Often there is no indication of the locations of the sensors corresponding to the parameters being plotted, but rather simply a tabular list of parameter names and the current values of the parameters. For this reason, a system operator is unable to determine the locations of the sensors by simply looking at the user interface. It can be difficult to determine the location of the sensors. Location determination may involve the system operator speaking with a software engineer to identify the electrical signal matching the name displayed in software. This is followed by the system operator checking an interconnect and/or a piping and instrumentation diagram to determine (i) a component number of the sensor, and (ii) what components the sensor is connected to and/or nearby in the tool. The system operator then, based on the component number and the identified components, spends time finding the actual physical location of the sensor. The process for determining the location of the sensor can be both time and labor intensive.

Not knowing where the sensor is located increases troubleshooting difficulty, as well as obfuscates possible broader conclusions that can be drawn from the collected data. In addition, it can be difficult to differentiate sensor data to detect that an unacceptable and/or degraded condition exists. For example, a tool may have many different temperature sensors. If one of the temperature sensors is reading a particularly high temperature, it may be difficult to determine if that temperature is within a reasonable range or is an indication that a corresponding component is running hotter than normal. If the processing module is running hot, the sensor data is probably fine, but one or more other conditions may need to be checked. In some cases, a threshold reset feature indicating a potential false alarm may be checked and if ON, then an issue likely does not exist. If however, the threshold reset feature is OFF, then a condition may exist and maintenance may be scheduled. In some cases, if the processing module is running below normal operating temperatures, then maintenance should be scheduled for a corresponding bank of sensors. It is difficult to apply process control limits to sensor data of these types of conditional scenarios. For these reasons, it is important for traditional tools to have a skilled technician troubleshoot an issue and correctly interpret sensor data values.

To record data, a tool may allow a diagnostic trace of a sensor data stream to be initiated by a system operator via a first system operator input (e.g., pressing a start button). The recording stops after a set amount of time or in response to a second system operator input (e.g., pressing a stop button). Pressing a button to start data recording works well when the system operator is running controlled tests, but does not work well when trying to capture repeated events that occur occasionally during normal processing periods and/or over extended periods of time. Recording data based on manual controls also causes large amounts of unnecessary data to be collected, which quickly fills up available memory.

The embodiments set forth herein include a system health monitoring, assessing and responding (HMAR) system that monitors sensors of a tool (or platform), and based on sensor data, assesses states of the tool. According to some embodiments, this includes generating health index (HI) values for individual sub-systems, modules, devices, components, sensors, etc. and generating an overall system health index (SHI) value. In some embodiments, the SHI value is generated based on an aggregation of the HI values. Each individual HI value is determined using one or more algorithms that are based on knowledge of potential failure modes of the tool. This approach is different than using a machine-learning algorithm to evaluate a large amount of historical data. Use of a machine-learning algorithm based on historical data requires a large amount of system memory and computational power and is similar to “digging for a needle in a haystack”. The disclosed aggregation method significantly reduces the amount of data stored and evaluated and thus reduces memory usage, data processing time and computational power needed to assess the state of the tool. In some embodiments, the tool may perform various actions in response to the SHI value and/or other HI values, as further described below.

The system assesses collected sensor data in real time, meaning during normal and/or abnormal processing operations. Collecting and assessing data during normal processing periods provides a more direct measurement and assessment of the behavior that affects processing results. Continuous checking is implemented over set periods of substrate processing time to provide a measure of what is occurring on the tool during processing and while substrates are being cycled through the tool. Running continuously for extended periods allows for a better prediction of when a component is to fail. Collecting data more frequently and during processing allows the data to be synchronized with process results.

The embodiments set forth herein also include sensor mapping, which includes displaying identifiers (IDs) of sensors, locations of sensors, and states of the sensors. This allows a system operator to quickly and easily determine the ID, physical location (hereinafter “location”) and state of each monitored sensor by simply looking at a user interface (UI). The data output values of the sensors may be shown versus time on the same screen and/or window or a different screen and/or window as the ID, location and state of the sensor. In some embodiments, data values versus time may be shown via a plot by clicking on a box indicating the sensor ID, location and current state. HI values associated with the sensors may also be indicated. The sensor information may be displayed using one or more UI screens and/or windows. The UI screens and/or windows may include graphical images of the corresponding tool and/or portions thereof with overlaid sensor information. The system may select which sensors to concurrently monitor and view corresponding data. In some embodiments, the selection is performed by a system operator.

Displaying the location of sensors allows system operators to quickly and easily identify trends between the sensor values and system performance, especially when a large number of sensors are utilized on a tool. Displaying the location of the sensors also allows an engineer to troubleshoot an issue with the tool more easily. Traditionally, an engineer may spend hours to simply track down and locate a sensor associated with an improper (or out of the normal) sensor reading. This may include emailing people to determine the location of the sensor and combing through documentation. The engineer may also incorrectly determine that the sensor is on a first component of the tool and begin troubleshooting the first component and sometime later determine the sensor is located on a second (or different) component. Since the engineer was troubleshooting the first component instead of the second component, the troubleshooting process needs to be restarted causing further downtime. Displaying the locations of sensors saves time locating the sensors and troubleshooting an issue to determine the root cause of the issue.

In some embodiments, automatic start and stop of datalogging is implemented based on sensor outputs, determination that certain conditions exist or may occur in the near future, thresholds, trigger events, etc. In some embodiments, the disclosed system allows a system operator to setup start and stop trigger events. Datalogging then automatically begins and stops when the trigger events occur. Limits and other conditions may be set for example to limit data retention time. Limits and other conditions may also be set to cause a timeout of datalogging when a stop trigger does not occur after a predetermined period of time from when datalogging began. In some embodiments, datalogging may be disabled after a preset time period (e.g., a day, a week, etc.). In some embodiments, the datalogging may be started based on HI values and/or corresponding information. In some embodiments, if a component is behaving oddly or beginning to degrade, such that performance is deteriorating, then the system may start datalogging of sensors directly associated with and/or indirectly affected by the component. The system may also extend datalogging of those sensors to collect additional data to analyze, monitor corresponding deteriorating aspects, and/or detect one or more issues. The automatic datalogging may be applied to low-speed and high-speed datalogging of a tool. In some embodiments, a tool may perform low-speed datalogging at about 20 hertz (Hz) for certain sensors and high-speed datalogging (e.g., about 1 kilo-hertz) for other sensors. In some embodiments, the system may determine a first set of one or more sensors for which low-speed datalogging is performed and a second set of one or more sensors for which high-speed datalogging is performed.

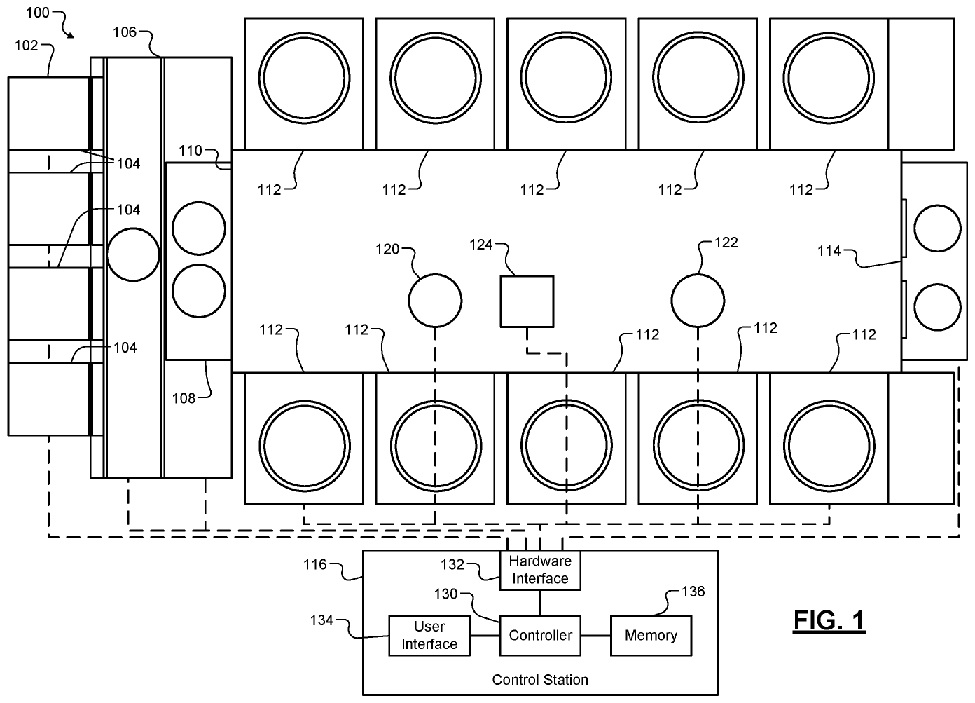

FIG. 1 shows a portion of a HMAR system 100 that includes a load port module (LPM) 102 with front end unified pods (FOUPs) 104, an equipment front end module (EFEM) and load lock (hereinafter “EFEM”) 106, an airlock 108, a vacuum transfer module (VTM) 110, processing modules (or stations) 112, a power lock out and tag out system 114, and a control station 116. The LPM 102, the EFEM 106, the airlock 108, the VTM 110 and the power lock out and tag out system 114 may be referred to as a platform. Substrates are initially received and stored in the FOUPs 104 and transferred to the processing modules 112 to perform various deposition, etch and cleaning processes. The VTM 110 transfers wafers to and from the stations 112. The VTM 110 may include robots (example robots 120, 122 are shown) and one or more buffers (one 124 is shown) for temporary storage of substrates. The robots transfer substrates to and from the stations 112 and the buffer(s). The platform in combination with the processing modules 112 may be referred to as a substrate processing system. Each of the stations 112 may be used to, for example, etch substrates using radio frequency (RF) plasma. Each of the stations 112 includes a processing chamber, such as an inductive coupled plasma (ICP) chamber or a conductive coupled plasma (CCP) chamber. The stations 112 may, for example, perform conductive etch or dielectric etch processes.

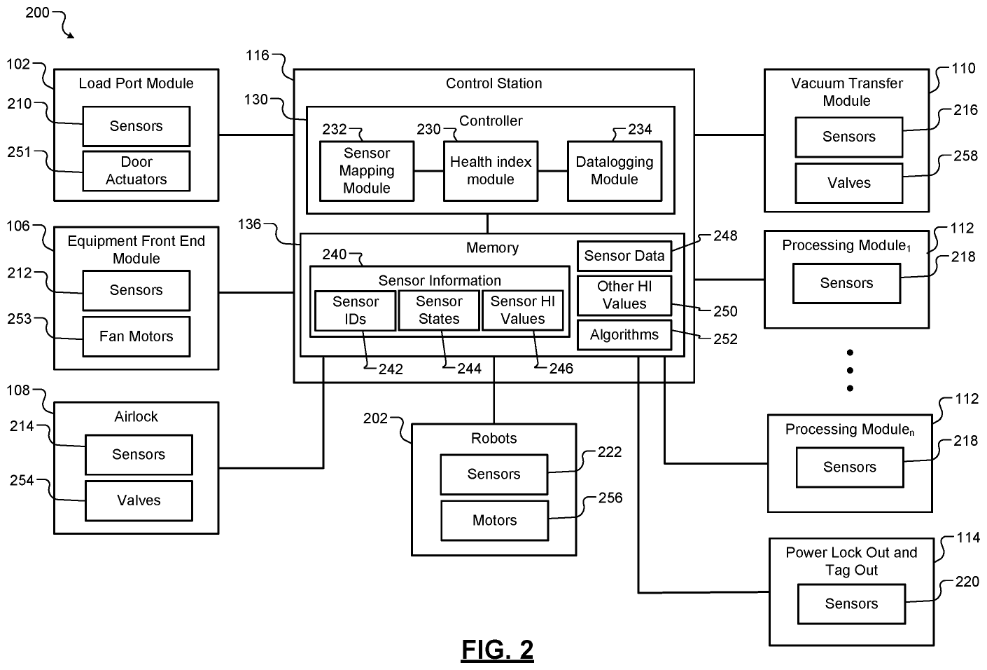

The control station 116 may control operation of the platform and the processing stations 112. The control station 116 may include a controller 130, a hardware interface 132, user interfaces 134, and a memory 136. The hardware interface 132 may be electrically connected to the LPM 102, FOUPs 104, EFEM 106, airlock 108, VTM 110, stations 112, power lock out and tag out system 114, and robots. The controller 130 may control and monitor the LPM 102, FOUPs 104, EFEM 106, airlock 108, VTM 110, stations 112, power lock out and tag out system 114, and robots. This includes monitoring sensors of the LPM 102, FOUPs 104, EFEM 106, airlock 108, VTM 110, stations 112, power lock out and tag out system 114, and robots. In some embodiments, the controller 130 is a general-purpose computer/processor. In some embodiments, the controller 130 is a special purpose computer/processor configured to interact with or command a specific set of sensors and programs in a wafer fabrication equipment. Example sensors are shown and described with respect to FIG. 2. The user interfaces 134 may include one or more displays, such as one or more touchscreens, a keyboard, etc. The memory 136 may store data collected from the sensors and other data and information as described below.

FIG. 2 shows a portion 200 of the HMAR system 100 including the LPM 102, EFEM 106, airlock 108, VTM 110, stations 112, power lock out and tag out system 114, and the control station 116. The portion 200 may also be referred to as a sensor mapping system and/or a datalogging system. The portion 200 also includes robots 202, which may include the robots 120, 122. The LPM 102, EFEM 106, airlock 108, VTM 110, stations 112, power lock out and tag out system 114, and robots 202 may include respective sensors 210, 212, 214, 216, 218, 220, 222. The sensors 210 of the LPM 102 may include pressure sensors, vibration sensors, etc. The sensors 210 may include, for example, a compressed dry air (CDA) pressure sensor and a door vibration sensor.

The sensors 212 of the EFEM 106 may include pressure sensors, temperature sensors, relative humidity (RH) sensors, oxygen sensors, concentration sensors, vibration sensors, flow rate sensors, speed sensors, particle sensors, etc. The sensors 212 may include: cameras; frame vibration sensors; fan filter unit flow rate sensors; fan speed sensors; printed circuit board (PCB) temperature, RH and pressure vibration sensors; nitrogen temperature sensors; nitrogen pressure sensors; etc. The sensors 214 of the airlock 108 may include pressure sensors, oxygen sensors, vibration sensors, RH sensors, temperature sensors, particle sensors, etc. The sensors 214 may include cameras, door vibration sensors, door CDA pressure sensors, etc.

The sensors 216 of the VTM 110 may include pressure sensors, temperature sensors, RH sensors, oxygen sensors, vibration sensors, etc. The sensors 216 may include: cameras; rocker valve vibration sensors; and PCB temperature, RH and pressure vibration sensors. The sensors 216 may include accelerometers that are on rocker valves. The sensors 218 of the stations 112 may include temperature sensors, pressure sensors, concentration sensors, voltage sensors, current sensors, etc. The sensors 220 of the power lock out and tag out system 114 may include temperature sensors, vibration sensors, etc. The sensors 222 of the robots 202 may include temperature sensors, vacuum pressure, vibration sensors, position sensors, voltage sensors, current sensors, etc. The sensors 210, 212, 214, 216, 218, 220, 222 and/or associated hardware may have associated analog inputs, digital inputs, analog outputs, and/or digital outputs, which may be provided by and/or received by the controller 130. Although some examples of the sensors 210, 212, 214, 216, 218, 220, 222 are stated-above, the sensors 210, 212, 214, 216, 218, 220, 222 may include other sensors, such as cameras and/or other sensors.

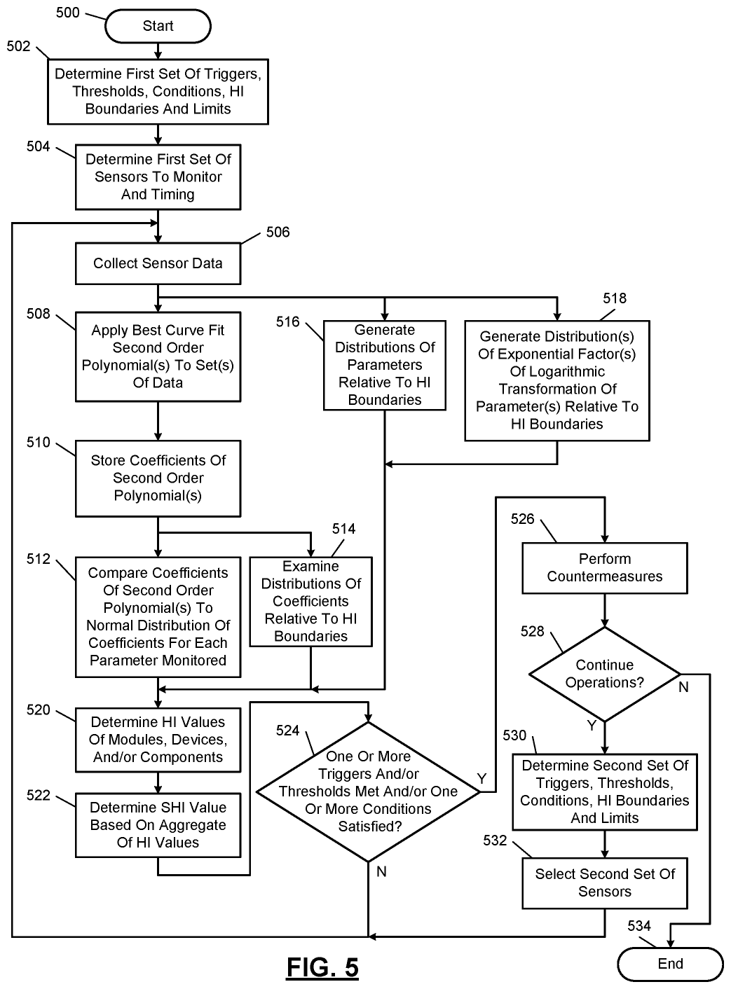

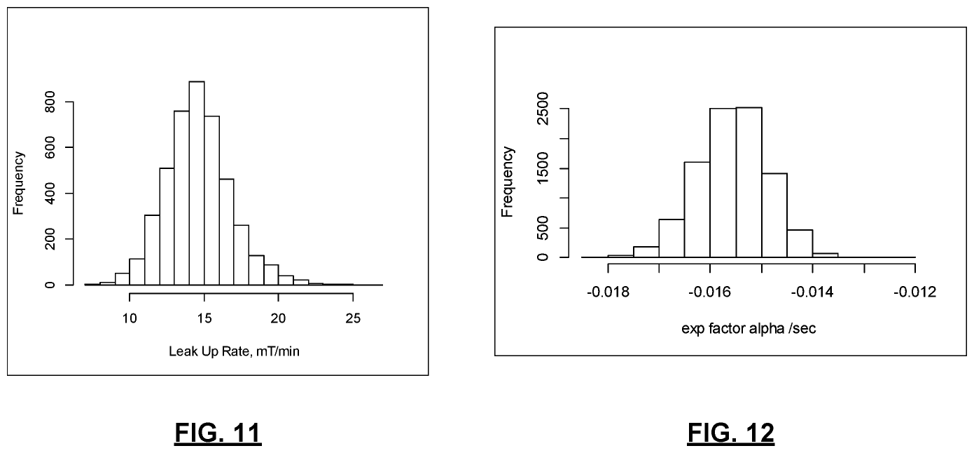

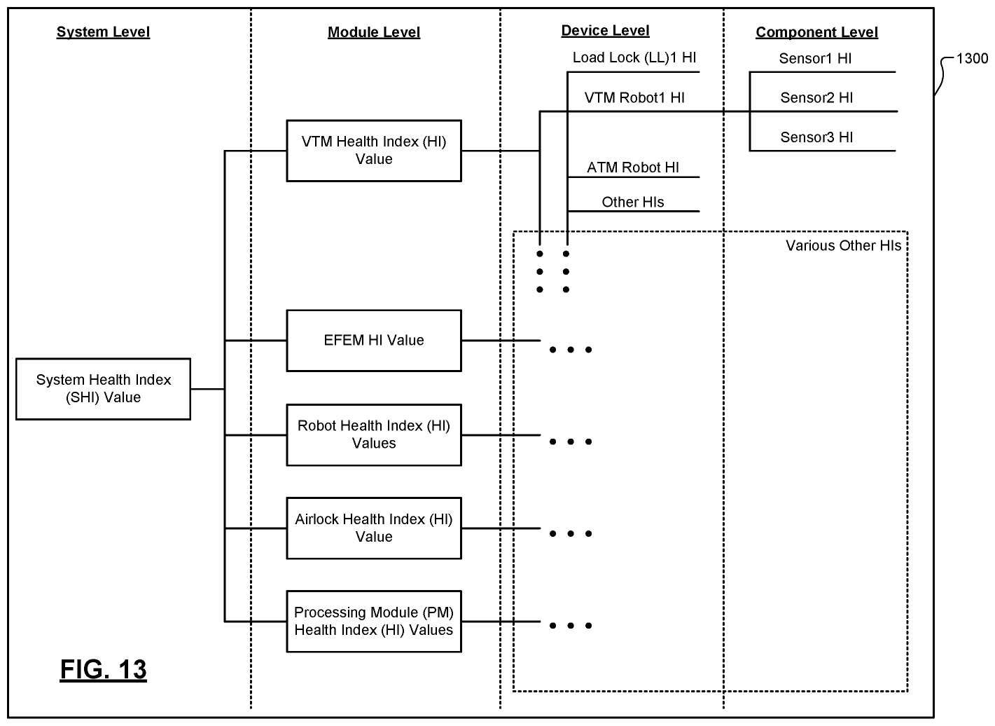

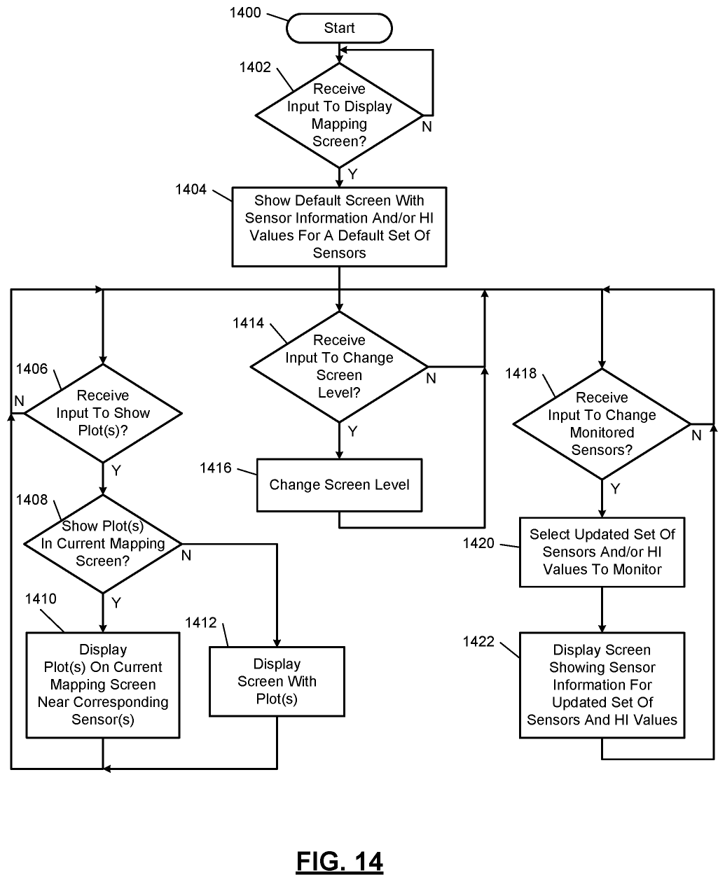

In some embodiments, the controller 130 includes a HI module 230, a sensor mapping module 232 and a datalogging module 234. The HI module 230 determines HI values of components and/or devices, such as the sensors 210, 212, 214, 216, 218, 220, 222, and other components and/or devices. The HI module 230 also determines HI values for modules, sub-systems and the substrate processing system, which may include the platform and/or the processing modules 112. Example embodiments of how the HI values may be determined are described below with respect to FIGS. 5-13. FIG. 13 shows an example hierarchical diagram with HI values for different hierarchical levels of the substrate processing system.

The sensor mapping module 232 determines sensor information, which is stored in the memory 136. The memory 136 stores: the sensor information 240 including sensor identifiers (IDs) 242, sensor states 244, and sensor HI values 246; sensor data 248; other HI values 250; and algorithms 252. The other HI values 250 may include system, module, device and/or component HI values. The sensor states 244 may be current outputs of the sensors 210, 212, 214, 216, 218, 220, 222 such as current operational status or parameters (e.g., temperature). The sensor information 240 may include other sensor information, such as a historical aggregate value. The sensor IDs 242 may include a part number, a serial number, unique labels, or any combinations thereof. The algorithms 252 may include any algorithms disclosed herein, which are executed by the controller 130.

During operation, the HI module 230 may provide instructions to the datalogging module 234 for performing datalogging operations according to some embodiments. The instructions may include sensors to monitor, periods to collect data from the sensors, frequency to collect data, collection size, resolution (or sampling rates), etc. The datalogging module 234 may perform datalogging including collecting data from the selected sensors based on the received instructions. The HI module 230 may then receive data collected by the datalogging module 234. The HI module 230 may also provide instructions to the sensor mapping module 232 for displaying sensor information and data plotting. This may include providing sensor IDs, periods to display information and/or data associated with the provided sensor IDs, whether to display sensor information and/or data, whether to plot data from multiple sensors, etc. The HI module 230 may receive sensor layout maps and values from the sensor mapping module 232. The sensor mapping module 232 may receive inputs indicating locations of sensors, sensor state values (e.g., logged data from datalogging module 234), boundaries and/or conditions from the HI module 230, etc.

The HI module 230 may perform sensor data tracking during normal process conditions, abnormal process conditions and/or other conditions. This may occur while the tool is idle and/or during processing. This may include predetermined, periodic, random, and/or semi-random tracking. In some embodiments, the HI module 230 tracks and determines sensor data evaluation (deltas over time, trends, etc.). The HI module 230 provides correlation of: data of each sensor tracked individually; data from sensors in same processing station; data from sensors in different processing stations; data from sensors in different processing modules; data from sensors of different tools when multiple tools are monitored; and any combinations mentioned above. In some embodiments, the HI module 230 determines slopes of data curves, timing for slope determination, weighting values of different sensors, etc. when evaluating whether certain conditions exist.

In some embodiments, the HI module 230 also performs aggregation, which may be local and/or semi-local based, station based, device based, module based, processing module based, and/or tool based. The aggregation may be for a group of similar and/or different sensors, related sensors and/or unrelated sensors, etc. The HI module 230 selects lowest correlation and/or aggregation values, as further described below. The HI module 230 monitors distributions, means, standard deviations, and shifts in parameters and HI values. The HI module 230 correlates aggregation values for: the same components, devices, modules, sub-systems, processing stations; and values for different components, devices, modules, sub-systems, processing stations. In some embodiments, the HI module 230 evaluates and correlates parameters and aggregation values to provide health index scoring, which may include comparing aggregation values and selecting a lowest aggregation value.

The HI module 230 further performs operations for: trend recognition; degradation recognition; regression analysis; early warning indications; status reporting of sensors, stations, processing modules, tools, etc.; and determining and reporting troubleshooting results. The HI module 230 generates instructions for datalogging including selecting sensor(s) for data collection, timing for one or more actions being performed, and frequency of sampling. The HI module 230 provides categorical boundary setting, resetting and updating including: alarm limit setting, resetting and updating (focusing, broadening, and/or shifting); decision boundary setting, resetting and updating (focusing, broadening, and/or shifting); normal operating range setting, resetting and updating (focusing, broadening, and/or shifting); setting adjustments based on system operator inputs; etc. This includes baseline setting and/or updating. The HI module 230 also may perform preventative maintenance and/or countermeasure operations based on results of correlations and aggregations including providing health status reports, warning reports, preventative maintenance indications, shutdown indications, shutting down operations, etc. As an example, the health status reports may include indications health status indications including one or more health index values, data plots, sensor location information, sensor output values, and/or other status information disclosed herein. The HI module 230 may compare data streams to find interactions and updating models, boundaries, etc. for degradation predictions, reporting and preventative maintenance and/or countermeasure initiation. The HI module 230 may also perform data deduplication and/or cleaning to minimize the amount of data storage.

The sensor mapping module 232: identifies and labels sensors; determines locations of sensors; indicates output states of sensors; and provides a two-dimensional (2D) and/or three-dimensional (3D) mapping and graphical displaying of sensor locations and other sensor information according to some embodiments. The sensor mapping module 232 may also plot data from selected sensor(s) in response to sensor selection (e.g., clicking on portion of display where sensor location is shown and displaying graph of sensor output over time). The data may be plotted based on selected periods of time and/or displayed as a sliding window of plotted sensor data. The data from multiple sensors may be timestamped and plotted on a same graph and/or in same window. The sensor mapping module 232 may set the graphical displaying and/or data plotting for different sets of sensors for different periods of time based on a predetermined datalogging/displaying plan. This may be set and/or adjusted based on system operator inputs. The sensor information displayed may include warnings and/or alerts. A different set of data may be collected from each sensor monitored. Thus, when multiple sensors are monitored, multiple sets of data are collected.

The sensor mapping module 232 may color code locations and/or values of the sensor information displayed. This may be done to indicate whether values are in predetermined boundaries/ranges, near the boundaries, or outside of the predetermined boundaries/ranges. This may also or alternatively be done to provide a virtual heat map when, for example, multiple temperature sensors are monitored. Correlation and/or aggregation values may be plotted and be based on system operator inputs.

The datalogging module 234 performs multi-sensor time based triggering and event based triggering of data collection from selected sensor(s) based on one or more triggering events and/or predetermined multi-event condition sets according to some embodiments. In one embodiment, pre-event triggering data collection from selected sensor(s) is performed. The event and pre-event triggering may be performed based on system operator inputs. Timeout of datalogging may occur when a trigger stop event is not detected and/or when a predetermined amount of data is collected. The datalogging module 234 sets datalogging for different sets of sensors for different periods of time based on a predetermined datalogging plan. This may be set and/or adjusted based on system operator inputs. The datalogging module 234 may perform data buffering and looped buffering and collect data from sensors directly associated with an event and/or from other sensors indirectly related to the event. The datalogging module 234 sets and tracks whether a predetermined total number of a same particular event has occurred to trigger data collection by a predetermined set of sensor(s). The datalogging module 234 may report data in real time (i.e. when collected and/or captured) and while continuing to perform datalogging. The number and types of triggering events and/or multi-event condition sets may be narrowed, maintained and/or broadened based on instructions from the HI module 230.

The controller 130 may monitor states of and control various devices based on the sensor information collected and HI values generated according to some embodiments. In some embodiments, an HI value is generated for each set of data collected. FIG. 2 shows some example devices including LPM door actuators 251, EFEM fan motors 253, airlock valves 254, robot motors 256 and VTM valves 258. Other devices may be included, monitored and controlled. The devices may also be controlled based on trigger events, thresholds being exceeded and/or other conditions being met. The devices may be controlled as part of countermeasures being performed.

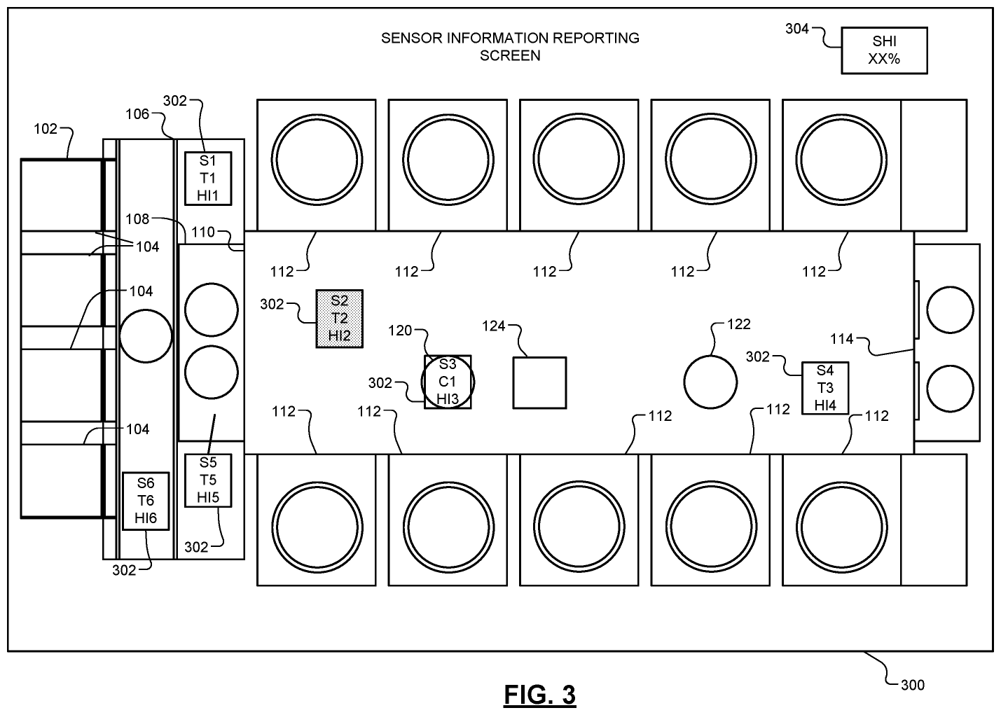

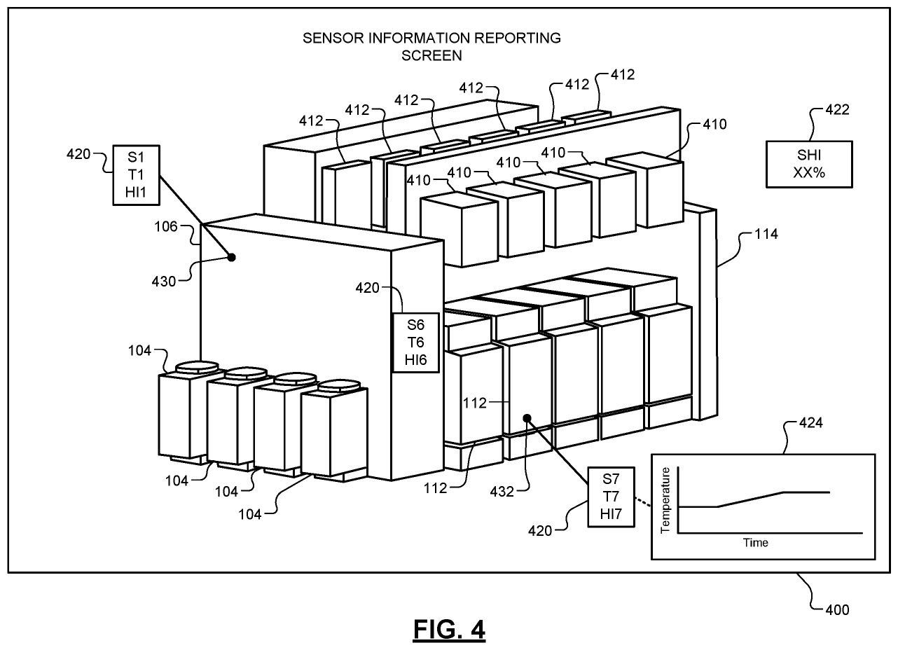

FIG. 3 shows a 2D sensor information and HI reporting screen 300, which may be displayed on, for example, one of the user interfaces 134 of FIG. 1. The screen 300 is provided as an example, other screens showing physical locations of sensors and sensor information may also be shown. In one embodiment, a system operator is able to select a screen to view and is able to “zoom in” on the physical location of the sensor and surrounding system hardware to easily pinpoint the location of a sensor. The screens may include 2D views or 3D views of hardware. An example 3D view is shown in FIG. 4. In one embodiment, numerous sensors (e.g., more than 20 sensors) are implemented and used as a heat map indicating temperatures throughout the substrate processing system and respective locations of the detected temperatures. Various other parameter maps may also be indicated along with the heat map of different temperatures.

The screen 300 of FIG. 3 is an overhead view of the substrate processing system including the LPM 102, FOUPs 104, EFEM 106, airlock 108, VTM 110, stations 112, power lock out and tag out system 114, robots 120, 122, and buffer 124. Multiple example sensor information blocks 302 are shown. The sensor information blocks 302 include sensor IDs, sensor state values, and HI values. Example sensor IDs S1-S6, sensor state temperature values T1-T6, a sensor state motor current value C1, and HI values HI1-HI6 are shown. The sensor information blocks are provided as examples. Any number of sensor information blocks may be shown. The number of sensor information blocks and the content of the sensor information blocks may be customized by a system operator. Aggregated HI values for devices, modules, sub-systems and/or the substrate processing system may also be displayed. An example SHI value block 304 is shown indicating the overall SHI value for the substrate processing system.

FIG. 4 shows a 3D sensor information and HI reporting screen 400. The screen 400 shows the substrate processing system including the FOUPs 104, the EFEM 106, processing modules 112 with radio frequency generators 410 and gas boxes 412, and the power lock out and tag out system 114. Example sensor information blocks 420 and a SHI status block 422 are shown. A system operator may tap or click on one of the sensor information blocks 420 to display a plot of the senor output over time. An example plot 424 is shown for the sensor S7. In one embodiment, the system operator is able to click on a particular location and is provided with plots of sensors in that location and/or in a nearby vicinity. In some embodiments, a single graph may be provided including plotted outputs of multiple sensors over time. This allows a system operator to see the changes in the corresponding parameters and determine whether an issue exists and the cause of the issue.

In one embodiment, the screens of FIGS. 3-4 and/or other sensor information screens includes dots identifying the locations of the respective sensors. A couple of dots 430, 432 are shown in FIG. 4. In some embodiments, the 3D screen may include a greyed out computer aided design (CAD) model with sensors and corresponding locations shown in red. In some embodiments, a UI may display a tabulated list of sensors with or without respective values of the sensors. A user may click on and/or select one or more entries (e.g., sensor IDs) in the tabulated list. When this occurs, the UI may transition to either one of the screens shown in FIG. 3 and FIG. 4 (and visa-versa). Also, in some embodiments, the controller 130 of FIG. 2 recommends other sensors to monitor and/or check based the previously selected sensor(s). The recommendation can be location based, sensor type based, operation condition based. For example, when clicking 432 in FIG. 4, the controller 130 may “pop up” a screen showing sensors in vicinity of where the user clicked. This may include showing additional and/or other sensors in the nearby region, which allows technicians to quickly check the status of the nearby sensors surrounding the point where the click occurred. In another embodiment, a “toggle” feature is included to enable and disable the recommendation of other sensors.

Sensor data may be plotted over time as described above. In an embodiment, the plotting may be set to begin at a certain time and on a certain day of the week. Other sensors data plotting may begin on a different time and day of the week. In yet another embodiment, sensor information is color coded. This may include color coding the sensor IDs, the sensors states, and the sensor HI values. The sensor states may be color coded to provide a heat map. In some embodiments, the color may be selected based on the sensor state value, a target (or specification) value for that sensor, and/or a difference between the sensor state value and the target value to show different color gradients. If, for example, sensor X is indicating 23° C. (corresponding specification of 20-23° C.) and sensor Y is 30° C. (corresponding specification of 28-32° C.), then sensor X is colder than sensor Y. The sensor state of sensor X may be represented with a color that is more towards blue on a color scale, whereas the sensor state of sensor Y may be a color, which is more towards red on the color scale. In some embodiments, sensor X is hot compared to the corresponding specification and has a sensor state with a color more towards red. Sensor Y is in the middle of the corresponding specification and has a sensor state with a green color, which is centrally located on the color scale.

FIG. 5 shows an example process for obtaining HI values according to certain embodiments. At least some of the following described calculations may be performed offline by an auxiliary computer or server or as described below. The data collected may be utilized as described and/or may be collated and stored in onboard and/or offboard memory for future calculations. The method may be performed with respect to the embodiments of FIGS. 1-4. The operations of the method may be performed by the HI module 230 of the controller 130, be iteratively performed, and begin at 500. At 502, the HI module 230 may determine a first set of triggers, thresholds, conditions, HI (or parameter distribution) boundaries and/or limits to periodically and/or continuously check for, report on, and respond to for safe and proper operation of the substrate processing system. The triggers may include indications of when to start and stop monitoring one or more sets of sensors, where each set of sensors includes one or more sensors. Sensor data may be compared to thresholds. Alarms and warning messages may be generated when one or more monitored parameters having exceeded the set thresholds. The thresholds may include parameter thresholds as well as HI boundaries and/or parameter minimum and maximum limits. Each of the conditions may include checking whether one or more parameters are at one or more predetermined values, levels and/or within predetermined ranges. A default set of triggers, thresholds, conditions, and/or limits may be used. One of the systems referred to herein and/or a system operator may create a customized set of triggers, thresholds, conditions, HI boundaries and/or limits, which may alternatively be used. The HI module 230 and/or other modules referred to herein may change the triggers, thresholds, conditions, HI boundaries and/or limits over time.

At 504, the HI module 230 may determine a first set of sensors to monitor and/or timing (start and stop times and/or trigger events) of the sensors. This may be an initial default set of sensors or a system operator selected set of sensors.

At 506, the HI module 230 collects sensor data from the currently monitored sensors.

At 508, the HI module 230 may apply a best curve fit second order polynomial(s) to set(s) of data collected from the sensors. A second order polynomial best-fit curve may be determined for each set of sensor data collected. FIG. 6 shows a parameter data plot including sensor data and a second order polynomial best-fit curve 600. In some embodiments, the plot may be associated with pressure within a load lock and be indicative of a leak up rate. The curve may be represented using, for example, equation 1, where p is pressure, t is time, and β₀, β₁, and β₂ are coefficients.

\hat{p}=β₀+β₁t+β₂t² (1)

At 510, the HI module 230 may store each set of coefficients of the second order polynomials for respective sensors in memory.

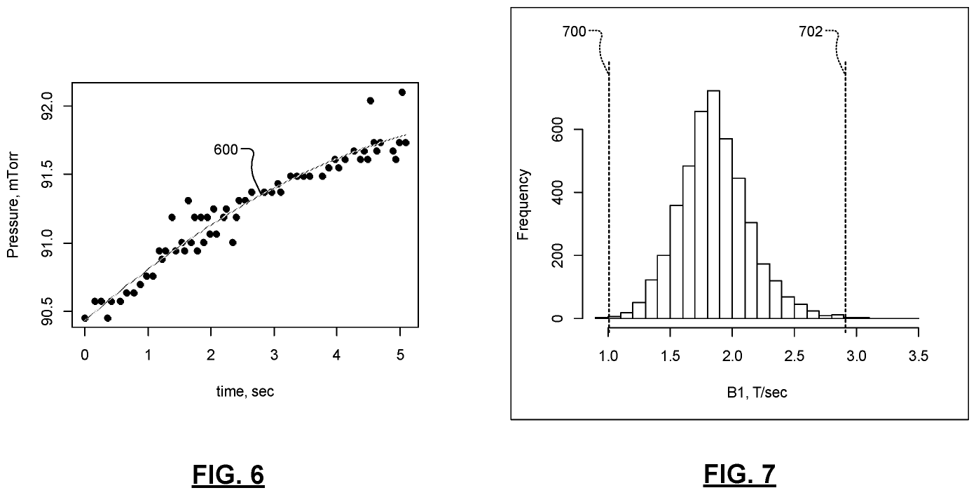

At 512, the HI module 230 may compare the sets of coefficients to a statistical distribution (e.g., a normal distribution) of coefficients for the corresponding parameters or alternatively at 514, the HI module 230 may examine distributions of the coefficients relative to HI (or parameter distribution) boundaries. The FIG. 7 shows an example coefficient distribution plot for a coefficient of the second order polynomial best-fit curve of FIG. 6. A coefficient distribution plot may be generated for each coefficient over time. Comparing the coefficients to a normal distribution provides a fast calculation for determining an HI value. This is quicker than, for example, comparing all data of a provided curve of plotted data to other curves and/or to a large set of historical data.

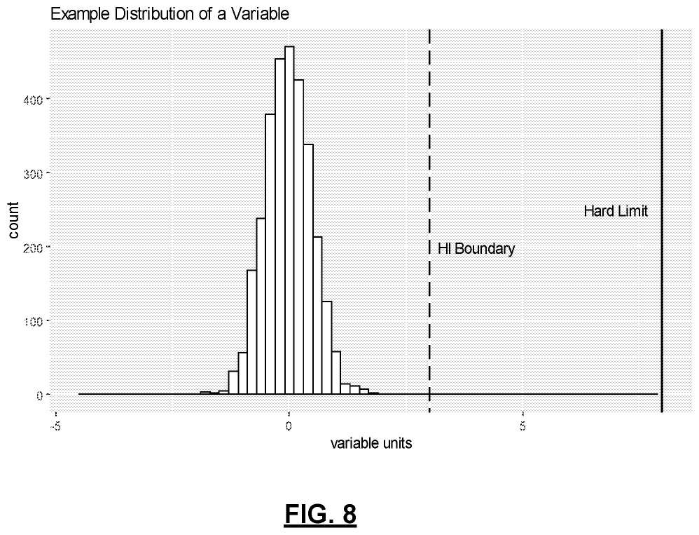

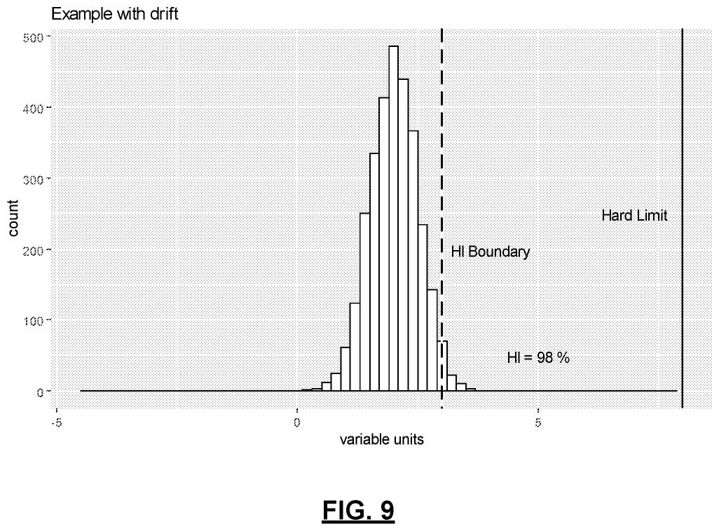

At 516, the HI module 230 may generate distributions of the sensor data. FIG. 8 shows an example parameter (or variable) distribution relative to one or more HI (or parameter distribution) boundaries and/or one or more hard limits. FIG. 9 shows the parameter distribution of FIG. 8 shifted relative to a HI boundary and a hard limit. This may occur over time and may occur due to degradation.

At 518, the HI module 230 may generate distributions of exponential factors of logarithmic transformations of parameters relative to one or more HI (or parameter distribution) boundaries. As an example degradation of a VTM door seal may be detected using this approach. A two-parameter model of pressure over time may be used using equation 2 or 3 and integrating to provide equation 4, where the log transformation provides a simple linear model having intercept Po and exponential factor alpha (a).

$$\frac{d P}{dt} = α P \qquad ( 2 )$$

$$\frac{d P}{P} = α dt \qquad ( 3 )$$

$$\hat{P} = {P}_{0} {e}^{- α} \qquad ( 4 )$$

FIG. 12 shows an example distribution of an exponential factor alpha α.

At 520, the HI module 230 may determine HI values of modules, devices, and/or components. Multiple different techniques may be used to determine an HI value. An HI value may be determined for each sensor. More HI values may be provided than there are sensors and/or components. This is because the HI values of multiple sensors and/or components may be aggregated to provide one or more additional HI values.

An HI value may be determined as a total number (or count) of normal values over a total number (or count) of events. A normal value refers to a sensor output value that is within a predetermined operating range for normal operation and/or a sensor output value that has not exceeded one or more predetermined thresholds associated with degraded or below normal performance operation. Similarly, a normal state of operation of a system, a module, a device, and/or a component may refer to when the one or more sensors associated with the system, module, device and/or component are within respective preset operating ranges identified as being associated with normal operation. Output values of the one or more sensors may not have exceeded one or more predetermined thresholds associated with degraded or below normal performance operation.

This may be implemented based on which of operations 508, 510, 512, 514, 516, 518 are performed. If operation 512 is performed, the HI value may be based on differences between the coefficients and the normal distribution of coefficients. In some embodiments, if operation 514 is performed, the HI module 230 may determine each HI value based on a percentage of the corresponding coefficient distribution that is within HI boundaries or above or below a HI (or parameter distribution) boundary. Example low and high HI (or parameter distribution) boundaries 700, 702 are shown in FIG. 7.

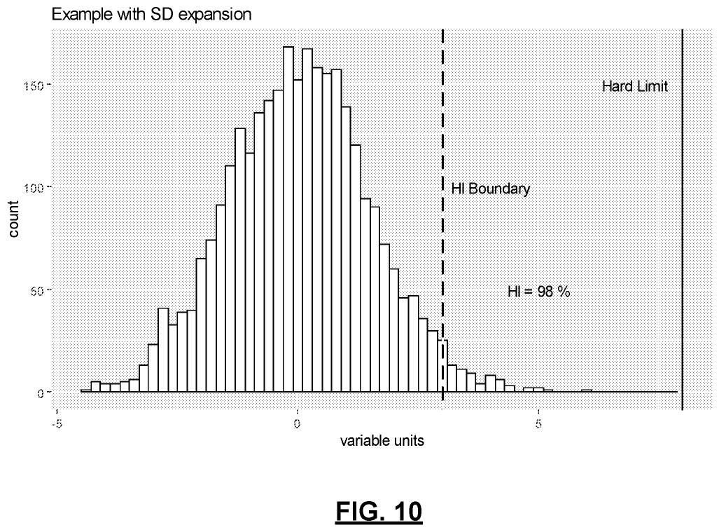

If operation 516 is performed, an HI value may be generated based on the percentage of the parameter distribution within the HI boundaries. FIG. 8 shows an example upper HI (or parameter distribution) boundary and an example hard limit for a particular parameter. If operation 518 is performed, then an HI value may be determined based on the distribution of the exponential factor and/or corresponding HI (or parameter distribution) boundaries, as similarly described above. FIG. 9 illustrates drift in the distribution of FIG. 8 closer to the high HI (or parameter distribution) boundary. The drift may be caused by degradation. FIG. 10 is shown to illustrate an increase in a standard deviation of the distribution of FIG. 8, which is also shown relative to the HI (or parameter distribution) boundary and the hard limit. An increase in standard deviation may occur due to degradation. The corresponding HI value decreases as the standard deviation increases.

Other techniques may be implemented to determine HI values. In some embodiments, a leak up rate may be monitored and an average slope of a plotted curve may be determined. An HI value may be determined based on the average slope of the curve. As the leak worsens over time, the HI value would be indicative of this change.

When multiple HI values are associated with a particular component, device or module, the lowest HI value is selected as the HI value for that component, device or module according to some embodiments. This provides a meaningful end result. If as an alternative the HI values are averaged, then the more HI values compared, the less meaningful the average HI value would be as far as determining the health of the component, device and/or module.

At 522, the HI module 230 determines the SHI value of the substrate processing system. This may include selecting the lowest HI value of the components, devices, modules and/or sub-systems. FIG. 13 shows an example hierarchical diagram screen 1300 having system, module, device and component levels shown. The system level includes the SHI value. The module level includes aggregated HI values for the VTM, EFEM, robots, airlock, and processing modules. The device level includes aggregated HI values for various devices associated with the VTM, EFEM, robots, airlock, and processing modules. The component level includes aggregated HI values for various components of each of the devices. The hierarchical diagram screen 1300 is an example display of HI values in a hierarchical format. The HI values for different levels are shown and the relationships between the aggregated HI values and HI values of a lower level are shown. Other hierarchical diagram screens 1300 may be shown. In one embodiment, hierarchical diagram screens 1300 are displayed for selected different areas of a substrate processing system.

At 524, the HI module 230 may determine whether one or more triggers and/or thresholds are met and/or one or more conditions are met. If yes, operation 526 may be performed, otherwise operation 506 may be performed.

At 526, the HI module 230 may perform one or more countermeasures. This may include generating one or more alarms and/or warning messages, which may be displayed on the one or more user interfaces 134 of FIG. 1. This may also include shutting down one or more devices, modules and/or systems. This may also include closing off a chamber, opening a door, evacuating a chamber, shutting down a robot, etc.

At 528, the HI module 230 may determine whether to continue operations. If yes, operation 530 may be performed, otherwise the method may end at 534. If the triggers, thresholds and/or conditions that are met are associated with degradation and the system is able to continue safely operating with at least predetermined levels of performance, operation 530 may be performed.

At 530, the HI module 230 may determine a second set of triggers, thresholds, conditions, HI boundaries and/or limits to check in subsequent iterations of this method. The first set of triggers, thresholds, conditions, HI (or parameter distribution) boundaries and/or limits may be changed based on previously met triggers, thresholds and/or conditions and/or changes in parameters values over time. The first set of triggers, thresholds, conditions, HI (or parameter distribution) boundaries and/or limits may also be changed based on system operator inputs. When it appears that a module, device and/or component is experiencing degradation, triggers, thresholds, conditions, HI (or parameter distribution) boundaries and/or limits may be set and corresponding sensors may be monitored more often and/or for longer periods of time. In addition, resolution of data collected may be increased for these sensors. The second set of sensors are selected at 532. Operation 506 may be performed subsequent to operation 532.

In addition to the above-described information, other information may also be determined and reported based on the HI values generated. In some embodiments, a reliability model may be generated for a remaining useful life (RUL) of a component, device, module and/or system based on the HI values. The HI values and/or other information may be monitored over time and used as an indication of degradation events and/or degradation of components, devices, modules, and/or systems. Degradation can occur slowly over extended periods of time. Interactions between different sensor data streams may be detected when monitoring outputs from multiple different sensors. The other information may include the sensor data, a first derivative of a parameter curve model to provide a rate change of the parameter, and/or other information. In some embodiments, a leak rate may be monitored and evaluated over time to determine whether degradation of a component has occurred.

In some embodiments, health of a robot may be determined based on tabular collected binary data points for different sensors over time. First-in-first-out (FIFO) buffers (or other buffers) of the memory 136 may be used to store data from the sensors. An HI value may be determined for each sensor and/or corresponding component or device. Each of the HI values may be determined as a mean of the values in the corresponding buffer. In some embodiments, each buffer may store 50 values for a respective sensor, where each of the values is a 0 or a 1. A row of values may be entered in the table when, for example, a robot move occurs. The HI value may be the percentage of values in a buffer that are a 1. The health of a motor may be a minimum of the corresponding HI values for that motor, which may be generated based on outputs of respective sensors. An example table is shown below including binary values, totals, and motor HI values for corresponding sensors. The binary values may be indicative of whether the parameter is within a corresponding predetermined range for normal operation. An aggregate HI value for the motor, which is the minimum of the HI values is also shown.

TABLE 1
Example HI values of a Robot

| | | | | W1 - | W2 - |
|---|---|---|---|---|---|
| Monitored | | | | Rotor | Rotor |
| Moves | Temp1 | Temp2 | Z-position | Speed | Speed |
| Move1 | 1 | 1 | 1 | 0 | 1 |
| Move2 | ↓ | ↓ | ↓ | ↓ | ↓ |
| . . . | | | | | |
| Move5 | | | | | |
| Move6 | | | | | |
| | ↓ | ↓ | ↓ | ↓ | ↓ |
| FIFO cell 50 | 1 | 1 | 1 | 0 | 1 |
| FIFO cell 49 | 1 | 1 | 0 | 1 | 1 |
| FIFO cell 48 | 1 | 1 | 1 | 1 | 1 |
| FIFO cell 47 | 1 | 1 | 1 | 0 | 1 |
| FIFO cell 46 | 1 | 1 | 1 | 1 | 1 |
| . . . | . . . | . . . | . . . | . . . | . . . |
| FIFO cell 3 | 1 | 1 | 1 | 1 | 1 |
| FIFO cell 2 | 1 | 1 | 1 | 1 | 0 |
| FIFO cell 1 | 1 | 1 | 1 | 1 | 1 |
| Totals | 48 | 50 | 49 | 47 | 49 |
| Motor Health | 96% | 100% | 98% | 94% | 98% |
| Indices | | | | | |
| Robot Health | 94% | | | | |
| Index | | | | | |

The above-described method and other features disclosed herein allow a system operator to easily troubleshoot an issue by quickly and easily being able to determine the locations of sensors and monitor data and information associated with the sensors. HI values may be monitored and the cause of the issue may be determined. The heath index values may also be used to determine when maintenance should be scheduled. The HI module 230 may provide recommendations regarding when to schedule maintenance and the types of maintenance needed based on the triggers, thresholds, and conditions met and the changes in parameters and HI values over time. When certain sets of HI values begin to degrade, respective issues may be detected and the HI module 230 may provide indications of the issues and suggested maintenance to correct the issues. As operation changes over time and parameters, distributions, etc. drift towards thresholds, boundaries or limits and alarms may be generated. This may include an HI value decreasing from an initial 100%. An alarm threshold being exceeded may be an indication to cease operation and stop the tool. The HI values may be used as a prediction of issues to come and/or of system, module, device and/or component performance.

The HI values may be generated hourly, daily, monthly, etc. depending on the component, device, module, system, historical data and/or operation, degradation and/or issue detected, etc. The frequency of data collection may be increased if an issue, a potential issue, and/or a degradation event has been detected. The HI module 230 may indicate an estimated useful life remaining of a component, device, module and/or system based on the HI values generated.

A normal operating condition of a machine (e.g., device, module, or system) is typically characterized in measurable parameters, which remain within a range that is typical of normal operation. Alarm conditions for a particular parameter may be set a considerable distance from a corresponding normal operating range. Thus, there is a range of operation that may be characterized as abnormal and outside of the normal operating range yet insufficiently deviant to cause an alarm condition and stop the machine.

It is possible to broadly classify such alarm conditions as being of either (i) a catastrophic nature (i.e. occurring with a very short period of time), or (ii) a degradation nature, which may occur over time frames of hours, days, weeks, or longer. In this latter case of longer degradation time, it is often the case that the degradation is indicated by associated parameters. The parameters may be out of the normal operating range and changing over time towards alarm thresholds. The above-described method includes detection of such conditions by computation of HI values.

The HI values are used to characterize the region in parameter space between normal operating conditions and alarm conditions. In this way, machine operators can be made aware of machine degradation while the machine is still operating in a condition that is considered acceptable (i.e. within the alarm conditions). In this manner machine operators are able to, without affecting machine productivity, assess the machine, schedule a maintenance operation, and assemble all the necessary tools, materials, and personnel needed for the maintenance operation. The health index computations are used to characterize the extent of the deviation of system operation from normal conditions, in a metric that ranges from 0% to 100%, where a value of 100% is considered normal (or good) machine operation.

One method for providing such health index computation results includes establishing one or more boundaries. This may include providing numerical levels in the machine parameter space, which serve to separate parameter regions of normal operation from regions of abnormal operation but which are insufficiently deviant to cause an alarm condition. Machine parameters may be divided into two classifications, an event-based classification and a continuous-based classification. For event-based parameters, each such event may be classified as either within the normal operating range for a parameter or outside of the normal operating range. A health index value may be calculated as the aggregation of such events (e.g., 50 such events), where the HI value is a fraction of such events, which occur within the normal operating range.

An example of an event-based health index value is an HI value provided for an amount of time to open a valve. The valve may have sensors providing signals indicating the open and closed states of the valve. Time to transition from closed to open is computed from these signals. There may be a normal variability around some mean execution time and a boundary value or values may be set outside this normal operation range but within the alarm limits. The health index value is the fraction of normal operations computed over a set of prior events (e.g., 50 events).

A more complex embodiment involves a transient process variable such as a pressure rise in an isolated vacuum chamber. Such a machine state might periodically exist during normal machine operation. A time period can be defined as the time during which the chamber remains fully isolated. During the stated time period, the pressure may typically drift up (or increase) as a vacuum is imperfect. However, in the case of seal degradation, this rate of pressure rise may increase over time.

A chamber pressured during an isolated condition may be acquired from a pressure sensor. The data acquired may be modeled by means of a second order linear model of pressure versus time, which may thereby provide an estimate of the leak up rate. Such a leak rate estimate may be treated in a manner similar to the valve timing example given above and a health index value calculated.

In some embodiments, a boundary may be set away from normal operating conditions for a temperature of a component, but within alarm conditions. A HI value may be scaled continuously between this boundary value and the alarm value. In this manner, an operating condition on the normal side of the boundary results in a HI value of 100%. The HI value is reduced as a machine parameter value approaches the alarm condition, at which point the health index value is 0%.

In some cases of continuous transient parameters, the triggering event is not under the control of the controller 130, but rather occurs in a process variable, which results from machine control actions indirectly. As such, these process variables may be used as triggers for defining the time interval over which the monitored parameter is acquired for the calculation of the HI value. In some embodiments, data acquisition of a pressure parameter may be triggered by a flow rate value rising above a trigger level, where such flow rate is not under the direct control of the machine controller.

Additionally, a change in a HI level may be used as a trigger to initiate collection of additional information. Such a trigger may be initiated at a particular level, such as when a HI value falls below 80%, or it may be a rate of change in the HI value over some period of time (e.g., a week). In some embodiments, a HI valve may degrade below a particular level (e.g., 90%) and the controller 130 is triggered to initiate collection of data from a vibration sensor during an extended period of time when ordinarily data would not be collected. The vibration sensor may be mounted on a valve and data from which may be ordinarily collected only periodically. Such additional information is collected as an aid to diagnosing the cause for the associated HI value degradation.

Alternatively, a HI value may be used to trigger scheduling and executing of a short diagnostic program, which serves to collect sensor data. The sensor data may be informative to diagnose degradation in the HI value. Such a short diagnostic program may take the corresponding machine off-line for a short period of time to execute test conditions, which are not feasible during normal system operation. The controller 130 may in turn use such diagnostic information to determine whether corrective action is required or the machine is taken off-line to avoid product misprocessing.

In some embodiments, the HI values provide initial points of troubleshooting and diagnosing and as such may be examined by service personnel and system operators in order to inform decisions regarding whether to take the machine off-line to perform corrective action. Complex machines can have numerous sensors each of which is specifically located to acquire particular information about the operation of the machine. A HI value may involve one or more sensor inputs. HI values may be shown along with other sensor information as described above to clearly identify the corresponding sensors and locations. This clarifies which sensors are employed in a HI calculation and where the sensors are physically located. A graphical image may be provided to indicate the locations of the sensors. This may include highlighting the sensors on a schematic and/or a pictorial representation of the machine.

### Types of Health Index Values

Multiple different types of HI values may be calculated. In some embodiments, the are separated into two general types: a categorical type where normal operation is defined and non-categorical type where normal operation is not clearly defined. The categorical method applies to cases where normal operation is able to be defined and deviation from normal operation is able to be detected. A straightforward example includes valve actuation. If a valve is operated 50,000 times and has an average actuation time of 0.5 seconds and it is anticipated that component degradation would likely manifest as a value becoming larger over time, then the values may be classified as either “normal”, or “abnormal” (or “suspicious”). A hard alarm may be provided at a first threshold and a machine may be stopped once the value reaches a second threshold that is higher than the first threshold. The second threshold may be associated with a problem or a throughput level that has degraded to an intolerable level. Any operation time up to the point at which the second threshold is met may be considered normal and operation is permitted to continue, but a “flag” may be generated when the first threshold is met. The first threshold being met indicates the component is degrading and as a result is investigated. First and second thresholds may also be used in association with HI values and similar operations may be performed.

The above curve-fitting embodiment that includes using a second-order polynomial curve fit may be referred to as a signal noise management technique used to reduce the curve and/or plotted data to a single HI value. The HI value is compared to a window, which corresponds to a normal (or good) range. The first categorical method is used when a normal operation is able to be defined. If performance shifts towards an upper or lower threshold and/or limit, some form of degradation is likely occurring. This may be indicative that the machine is likely to be shutdown and/or become inoperative in the near future. That is, system operation is exhibiting a trending behavior in an abnormal (or “bad”) direction and trending towards an alarm condition that may result in operation of the machine being stopped, which may be implemented by the HI module 230.

In the categorical method a HI value is generated based on a description of “normal” operation. In some embodiments, valve actuations of a newly manufactured valve which has passed manufacturing tests may be used to determine and define normal operation. The HI value may be allotted some natural variability, which is considered in the design and therefore not to be considered abnormal. One or more alarm limits may be used in association with the HI value. The alarm limits may be well outside normal operation and be sufficiently deviant to require tool operation interruption. The objective of the HI value calculation is to inform a system operator of subsystem degradation prior to such an extent that causes an unscheduled system shutdown.

The categorical HI algorithm establishes a decision boundary, which is set between the normal operating range and the alarm limit(s). The algorithm classifies events by which side of the boundary they occur, and calculates the HI as the fraction remaining on the “normal” side of the boundary. If the boundary is set relatively far from the normal operating range, then the HI value is 100% until such time as the operation has degraded sufficiently to cause some significant fraction of events to fall on the alarm side of the boundary. This results in the HI value degrading (or decreasing) towards zero. Indeed, the farther the boundary is located away from normal operation the longer the HI value is likely to be in the timespan before HI degradation is observed. However, a boundary set closer to the normal operating range provides a more sensitive and timely HI degradation value, albeit with fluctuations near 100% being provided.

The region of “normal” operation may vary by the particular operating conditions that customers employ. These may include or be based on the relative humidity and temperature of the ambient fab conditions, or the particular wafers processed that may outgas more than typical. It can thus be anticipated that the region of “normal” operation cannot always be universal and therefore hard coded into the algorithm. Thus, the categorical method may be adaptive to account for these changes.

### An Adaptive Algorithm for HI Computation

At an initial state, a sub-system may have passed a manufacturing test, been installed and verified by an installation team, and ready for production deployment. The sub-system is in a known normal state and as such characterization of the sub-system may be executed to establish the “normal” operation. The characterization boundary may be set depending upon the system operator's judgement of the required sensitivity to operational degradation.

Alternatively, the algorithm may be adaptive, selecting an initial boundary value out near an alarm level (e.g., a trial HI level of 80%), which is well outside the normal operating range. Then, as operation progresses, the algorithm may set a trial level inward towards the normal operating conditions. Based upon the occurrence of boundary crossings at the trial level, the initial boundary value may be moved inward towards the normal operating range. This process may proceed until certain threshold level is observed in the trial boundary level, at which time the algorithm ceases this trial process and adjusts the categorization boundary to be at the resulting boundary level. The categorical method may be resettable in the event of a service operation, which resets the sub-system to a new “normal” state. The algorithm then automatically repeats the process to provide a new categorization boundary level as described above. It is expected that this adaptive process occurs well within the degradation time span of the sub-system, such that the intended function of the HI value is not compromised. The boundary may only be moved inward, towards normal operation, such that it does not adapt to degradation conditions.

The second non-categorical method accounts for other situations, such as analog signals that must remain within window limits for proper tool operation, but no values within the allowed window limits are better/worse than any others. In some embodiments, certain sensor data may be collected, but normal operation has not been determined for data provided by the corresponding sensor. An upper boundary may be set, but all data below that boundary may be considered the same, as far as a degradation level. To provide a degradation indication based on this sensor data, a running average may be determined of the data and a corresponding HI value may be scaled over some range. In some embodiments, a sensor's (e.g., relative humidity sensor) hard limit may be set at 60%. An HI value of 0% may be assigned for values over 60%, since this is the alarm limit value. If the relative humidity sensor signal usually runs under 40%, then any value under 40% is assigned an HI value of 100%. At values between 40% and 60%, a running mean value of the relative humidity sensor signal is determined to provide an HI value linearly scaled from 40%-60%. This is done such that if the running average is, for example, 45% (or 25% of the way from 40% to 60%), then the HI value is set at 75%. As a result, it may be indicated that the RH value is increasing up towards the alarm limit and may warrant investigation.

### Provided Health Index Features

Various HI features may be implemented by the HI module 230. An algorithm that aggregates machine operations may be executed by the HI module 230. The algorithm may aggregate machine operations based on classifying whether such operations occur inside or outside of predefined normal operating conditions to provide a machine HI value. In other features, a hierarchical structuring of HI calculations corresponding to physical and/or functional decomposition of a machine are implemented. In other features, an aggregation algorithm is executed by the HI module 230 that uses Boolean operations corresponding to redundancy or lack thereof within each machine sub-system. In one embodiment, a Boolean value (e.g., 0 or 1, True or False), etc.) may be provided based on whether a first HI value is smaller than a second HI value. The smaller HI value may be selected based on this Boolean value. In another embodiment, similar Boolean values may be provided when determining redundancy of data values and/or HI values. If two values match and/or are indicative of a same value, then one of the value is removed (or discarded). In other features, a Boolean aggregation algorithm is executed by the HI module 230 at a given sub-system level which results in an aggregation to the minimum value of lower-level HI values at the given sub-system level. In other features, an algorithm is executed by the HI module 230 that includes a computation which results in a HI value between 0% and 100% inclusive, with the 100% level or a predetermined range from 100% is interpreted as machine operation under normal conditions.

In other features, an algorithm is executed by the HI module 230 that classifies a defined machine event as being either within normal machine operation or abnormal machine operation, but in an acceptable operating range limits (i.e. not warranting an alarm to be generated and/or a cease in machine operation).

In other features, an algorithm is executed by the HI module 230 that computes a HI value based on a set of events of sufficient size to be statistically meaningful. In other features, a last predetermined number (e.g., 50) of events are evaluated to define a data set for computation of a HI value. In other features, an algorithm is executed by the HI module 230 that generates a HI value, which is a fraction of observed events determined to fall within normal operation within the data set.

In other features, an algorithm is executed by the HI module 230 that: initially uses acquired data from an analog sensor over a time period defined by predetermined machine states; and then uses a mathematical model to compute a secondary value characteristic of machine operation during the defined time period. This secondary value is then used in any of the HI computations disclosed herein. In other features, an algorithm is executed by the HI module 230 that scales the HI value between a defined boundary level and an alarm level to indicate the severity of the machine operating condition beyond the boundary level. In other features, a similar algorithm is executed by the HI module 230 that uses nonlinear scaling. Linear scaling may refer to when different HI values are altered by a same amount and/or a same product. Non-linear scaling may refer to when different HI values in different ranges are altered differently. For example, first HI values in a first range may be altered differently than second HI values in a second range. As an example, the HI values in the first range may be multiplied and/or shifted by different amounts than the HI values in the second range.

In other features, HI values corresponding to functional or physical composition of the machine are displayed on a user interface. In an embodiment, an entire hierarchy of the machine or a portion thereof is displayed with corresponding HI values. In other features, machine operator inputs are received and based on the inputs, one or more hierarchical levels of HI values are hidden, and one or more other hierarchical levels of HI values are displayed. Various levels of HI metrics may be displayed at the discretion of the machine operator. Example HI metrics are “daily for a week”, “weekly for a month”, and “three prior months”. Historical values of the HI metrics may be displayed. Various aggregation levels of the HI metrics may be displayed and/or selectively displayed based on inputs from a machine operator. Physical locations of the sensors associated with the HI values and/or metrics may also be displayed as described above.

In other features, an algorithm is executed by the HI module 230 that determines boundaries of normal operation based upon operating the machine in a known normal state for sufficient time to create statistically valid boundary or boundaries delineating normal operation from abnormal operation. In other features, an algorithm is executed by the HI module 230 that uses the time interval between well-defined machine operations as a basis for the HI determination.

In other features, an algorithm is executed by the HI module 230 that uses the data generated by a sensor under specified machine operating conditions, for a period of time, which then applies a mathematical model to the data to reduce the data to a single value. The single value is used as a basis for the HI calculation. In other features, an algorithm is executed by the HI module 230 that uses multiple analog signals combined in a multivariate mathematical model to reduce the amount of data to a single value. The single value is used as a basis for HI calculation. In other features, an algorithm is executed by the HI module 230 that uses multiple analog signals not necessarily occurring simultaneously for use in such models. In other features, an algorithm is executed by the HI module 230 that computes a HI value on a periodic basis (e.g., hourly).

In other features, an algorithm is executed by the HI module 230 that computes an event-based HI value for each occurrence of a machine event. In other features, such an event is defined by the machine state under the command of the HI module 230. In other features, such an event is defined by the machine state of a process variable. In other features, the machine state is of a process variable, which may include excursion above or below a constant value. In other features, the machine state is of the process variable and may include a rate of change of crossing above or below a constant value. In other features, the machine state utilizes multiple process variables combined in a Boolean operation. In other features, the machine state is defined as a combination of multiple process variables by arithmetic operations. In other features, the machine state is defined as employing multiple process variables in a mathematical model.

In other features, an algorithm is executed by the HI module 230 that computes an HI value for a sampled subset of occurrences. In other features, an algorithm is executed by the HI module 230 that computes a HI value for a machine subsystem. The HI value is indicative of the degree to which machine operation approaches an alarm limit. In other features, an algorithm is executed by the HI module 230 that employs a continuously valued sensor reading and computes a HI value over a range of the sensor data. In other features, an algorithm is executed by the HI module 230 that utilizes a predetermined boundary value located between normal machine operation and the alarm limit. In other features, an algorithm is executed by the HI module 230 that linearly scales the HI value between the boundary and the alarm level, such that an HI value is 100% at the boundary and 0% at the alarm level.

In other features, an algorithm is executed by the HI module 230 that uses a HI level, or rate of change, to initiate data collection of one or more additional sensors. This data collection may be at a higher data rate than a standard operation. The additional data collection is used to augment the HI value data and better inform decisions regarding performance of corrective maintenance operations. In other features, an algorithm is executed by the HI module 230 that uses a HI level, or rate of change, to initiate or schedule execution of a short diagnostic program. The diagnostic program serves to collect sensor data, which may be informative to diagnose degradation associated with an original HI value. The short diagnostic program may take the machine off-line for a short period of time to execute test conditions that are not feasible during normal system operation.

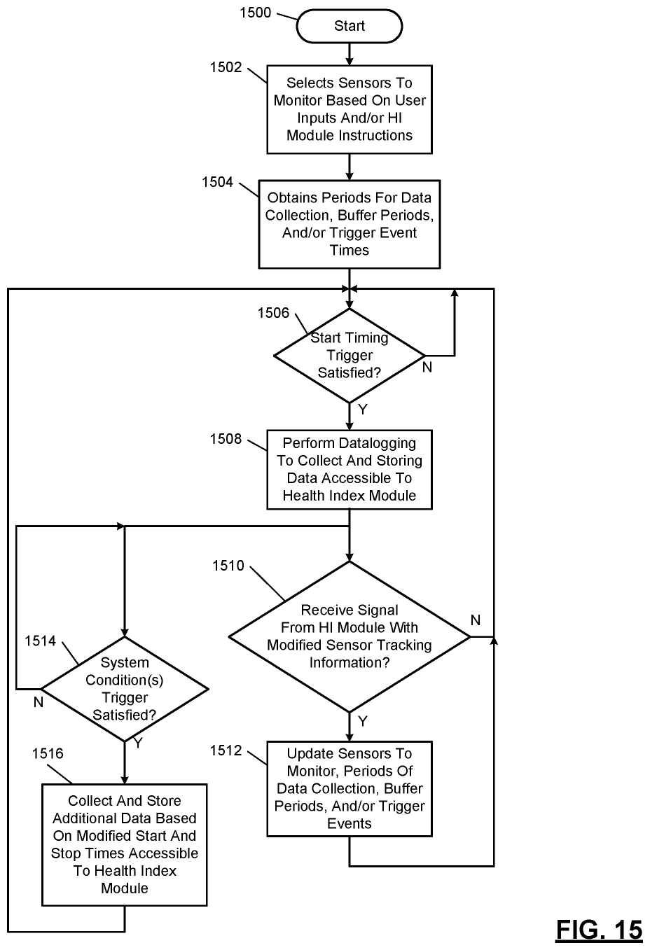

FIG. 14 shows a sensor information and HI reporting method according to certain embodiments. The method may be implemented by the sensor mapping module 232 and may be iteratively performed. The method may begin at 1400. At 1402, the sensor mapping module 232 may determine whether an input has been received to display a mapping screen, such as that shown in FIGS. 3 and 4. If an input to display a mapping screen has been received, then operation 1404 may be performed. At 1404, the sensor mapping module 232 may initially show a default screen with sensor information and/or HI values for a default set of sensors. In one embodiment, a pre-stored customized screen with preselected sensor information is displayed.

At 1406, the sensor mapping module 232 may determine whether an input has been received to show one or more plots for one or more sensors. The input may be received from a system operator or from the HI module 230. If yes, operation 1408 may be performed. At 1408, the sensor mapping module 232 may determine whether one or more plots are to be displayed in a current displayed mapping screen. If yes, operation 1410 may be performed, otherwise operation 1412 is performed. At 1410, the sensor mapping module 232 displays one or more plots, an example of which is shown in FIG. 4, on the currently displayed mapping screen near corresponding sensors associated with the plot(s). At 1412, the sensor mapping module 232 displays another screen with the one or more plots to display.

At 1414, the sensor mapping module 232 determines whether an input has been received to change a current screen level. The input may be from a system operator or from the HI module 230. In some embodiments, the current screen may a system level screen and the system operator may request to view a sub-system, module, device or component level screen. If yes, operation 1416 may be performed. At 1416, the sensor mapping module 232 changes the screen level and shows sensor information associated with the screen level selected and for an area of the system selected.

At 1418, the sensor mapping module 232 determines whether an input has been received to change monitored sensors. The input may be received from a system operator or from the HI module 230. This may include change the number and types of sensors currently being displayed for the screen level shown. If yes, operation 1420 is performed. At 1420, the sensor mapping module 232 selects an updated set of sensors and/or HI values to monitor. At 1422, the sensor mapping module 232 displays a screen showing sensor information for an updated set of sensors and HI values.

The controller 130 and/or the sensor mapping module 232 may use a machine learning algorithm to determine the relevant sensors that affect process performance. If the machine learning algorithm indicates that a particular sensor is the most related sensor to particle performance of a processing module, then this may be indicated to a system operator and the system operator may investigate the physical mechanism that aligns with that conclusion. A system operator may interpret machine learning results looking at the physical system and assessing what sensor outputs mean. The sensor information and data plotting allows the system operator to make hypothesis about trends in the data. Displaying the physical locations of the sensors reduces a barrier in allowing the system operator to discover trends in the data.

### Datalogging and Triggering

Actions by the substrate processing system and responses to the actions may happen on time scales ranging from milliseconds to hours. A default sampling rate of a sensor may be 20 Hz, which generates 20×3600×24=1.7 million (M) data points per day, per signal. If the sampling rate is increased to 1 kilohertz (KHz), that provides 50 times or 86M data points per day. The amount of data increases the more sensor signals monitored. Although multiple hours, days and/or weeks of data may be generated, an actual time window of interest may only be a few seconds long. This makes it difficult to find the actual data of interest. Also, the collection of that much data can require a large amount of bandwidth.

In an embodiment, only the data of interest is collected and a trigger is used to ignore uninteresting (or irrelevant) data prior to the time window of interest. In some embodiments, an instability in a matching network may be detected during a process sequence where a gas flow is changed. A trigger may be set based on the gas command changing the gas flow. The trigger value may be (i) an analog value either sent to or read back from a mass flow controller, or (ii) a digital event associated with a valve opening. Data may be collected in response to the trigger event. In some embodiments, a problem may occur 20 seconds after the gas command. A delayed trigger may be set with 15 seconds delay and data may be buffered for 10 seconds. As a result, data may be captured for 10 seconds prior to the trigger event and for some time thereafter. In an embodiment, multiple events may be used to define the trigger point. The events may be monitored via, for example, a binary signal (a valve transitions to an open state) and an analog signal (a mass flow controller output flow rate increases above 300 standard cubic centimeters per minute (sccm)). In some embodiments, the controller 130 may monitor for and detect when an intermittent trigger event and/or one or more conditions occur and buffer data in response to the triggering event and/or the one or more conditions occurring. The condition(s) may occur prior the triggering event. A triggering event may be an arcing event.

FIG. 15 shows a datalogging method according to certain embodiments. This method may be implemented by the datalogging module 234 and may be iteratively performed. The method may begin at 1500. At 1502, the datalogging module 234 may selects sensors to monitor based on system operator inputs and/or instructions from the HI module 230. At 1504, the datalogging module 234 may obtain periods for data collections, buffer periods, trigger event times and/or other information referred to herein. This may be from memory, user inputs and/or instructions from the HI module 230.

At 1506, the datalogging module 234 may determine whether a start timing trigger has been satisfied. If yes, operation 1508 may be performed. At 1508, the datalogging module 234 performs datalogging to collect and store data, which is accessible by the HI module 230. Datalogging may be performed for the selected sensors for which a start trigger has been reached and may end based on stop triggers.

At 1510, the datalogging module 234 may, when an instruction signal has been received from the HI module 230, perform operation 1512, otherwise perform operation 1506. The instruction signal from the HI module may indicate modified sensor tracking information, such as sensors to track, start and stop times, buffer periods, resolution/sampling rates, frequency of data collection, trigger events, etc.

At 1512, the datalogging module 234 may update the sensors to monitor, periods of data collection, buffer periods, resolution/sampling rates, frequency of data collection, trigger events, etc. based on the sensor tracking information received from the HI module 230.

At 1514, the datalogging module 234 may determine whether one or more system condition triggers have been satisfied. If yes, operation 1516 may be performed, otherwise operation 1506 may be performed. At 1516, the datalogging module 234 may collect and store additional data based on the modified start and stop times, where the data is accessible to the HI module 230.

A problem with some datalogging methods, which collect data at a start of a substrate process, is the difficulty in picking out a short transient in all of the collected data. Also, if monitoring for an occurrence in a sub-millisecond portion of a signal, a fast data rate and a large amount of bandwidth and memory are needed. By initiating data collection of a trigger event as in the above-described method, a time may be picked close to and prior to a suspected occurrence. As a result, relevant data is collected with minimal or no collection of irrelevant data. Additionally, if a monitored sensor signal is buffered, a trigger start may be provided prior to an event to monitor, by ending collection shortly after the event and reading out data buffered. In some embodiments, this is implemented when monitoring an arcing event, which is known to occur within a time window after a triggerable event, but the exact time is unknown. An optional trigger may be used to enable data recording and a looped buffer may be used to store the data captured for the arcing event.

Triggers may also be set that use logical operators and actions may be performed when multiple trigger events occur or when one or more conditions exist (e.g., trigger ON event A or signal X). Datalogging may be triggered ON one or more combination of events and collect data of several signals to investigate potential cause and effect relationships that are suspected as occurring. Triggers may also be defined for binary events (e.g., a power-ON command to a sub-system, a level of signal being reached, a pressure rising above a trigger level, etc.). To capture intermittent events, data may be recorded each time a triggering event occurs up to a predetermined number of occurrences. Then the corresponding tool may run unattended and post a note when the events are captured. This is useful for events that have hours between occurrences.

The above-described embodiments, which include providing an SHI value for an entire system and/or machine, allows for quick detection of a failure and/or issue. One reason for this is the frequency of SHI determination may be high and provided during system operation. The SHI value is able to be determined when the system is not in an idle state and often with minimal memory usage and processing power. The SHI approach allows for more efficient capturing of data surrounding known potential failure modes and the scheduling of maintenance. Both the aggregate status and the status of hardware of a particular module are monitored and used to schedule preventative maintenance as well as quickly identify issues that may adversely affect process results or equipment health. In some instances, aggregation is performed and presented for quick and easy human detection and understanding. In some instances, the aggregated information may be used to facilitate redistribution of work or reconfiguration/rearrangement of the modules to prolong the useful life of the overall system. Knowing which particular tools and modules are starting to show degradation allows system operators to schedule maintenance and route substrates in a fabrication environment to increase overall uptime and improve process results.

In some embodiments, the above-described methods may be implemented when an airlock has completed a pump down and there is at a least a 5 second pause before a VTM door is opened. Pressure data is logged and a second order polynomial is applied to compare coefficients of the polynomial to a distribution of coefficients. The system responds based on process control limits. Possible responses include posting a warning, changing the health index score, or simply saving data and not giving an indication to the system operator. These types of checks may be performed during normal cycling. In one embodiment, only coefficients of the best-fit second order polynomial are saved rather than all the pressure values collected and/or used in the calculation performed to provide the best-fit second order polynomial. Saving only coefficients is a huge reduction in memory needed, especially when running hundreds of algorithms. The described techniques may be applied to any continuous data trace. In some embodiments, the described techniques allow for slow shifts over time versus single outliers and minimize the possibility for false-positive reporting (e.g., reporting a tool is in abnormal health and yet the tool does not fail for a long period of time) and false-negative reporting (e.g., reporting a tool is in operating normally and the tool actually fails).

In some embodiments, the described sensor mapping and displaying sensor information allows broad conclusions about a system to be determined. In some embodiments, more than 20 temperature sensors may be included and temperature data from respective points on a substrate processing system are collected. If an environmental condition arises in a back half of the substrate processing system, the temperature sensors near where the condition occurred or elsewhere may have abnormal readings. In some embodiments, a VTM may show temperatures 5° C. higher than normal on average when all processing modules of the substrate processing system are running. It may be determined whether processing modules on the back half of the substrate processing system are providing the same or worse performance than normal and/or worse performance than the front processing modules. If yes, a determination may be made that an issues exists on the back half of the system.

In some embodiments, datalogging may be performed once every few nights of cycling 400+FOUPs of substrates (also referred to as wafers), where each FOUP may hold 25 substrates. An error may be detected when timing of valves on load locks are offset and create a pressure spike after pump down. An example resolution to capture a valve sequence and understand an error may be set to a sampling frequency of greater than or equal to 20 Hz. In some embodiments, datalogging may be performed to capture 1 second of high-speed data each time a loadlock is pumped down. This may be done without a system operator needing to push a start and/or stop button. The period during which the high-speed data is captured may be customized for the application. The datalogging of high-speed data may occur for a set period during each pump down and may be automated and triggered based on a load lock pressure. This allows a valve sequence to be monitored to determine (i) if the appropriate valve sequencing is occurring, and (ii) if there is an issue, a cause of the issue. The amount of data saved during event-triggered-logging may be 10 to 100 times less data than continuous datalogging for extended periods of time. Although continuous datalogging at 20 Hz over an extended period may allow an event to be captured, using the techniques disclosed herein, the event is able to be captured by collecting selected amounts of data over selected intervals (e.g., 1 second of data every minute), as opposed to collecting the full intervals worth of data.

For system health index calculations, reducing the amount of data logged reduces memory usage and processing power needed to generate HI values. HI values may be generated to allow detection of degradation (e.g., a valve degrading) or other operation abnormality. High-speed data for valve opening and closing may be logged for more detailed issue and cause detection. If data is being tracked for many components, the disclosed datalogging embodiments allow for a greatly reduced amount of data to be stored. Although all data may alternatively be continuously logged over an extended period of time, a large amount of memory and fast processing is needed to store and analyze this large amount of collected data. The amount of memory and processing equipment needed is expensive. The disclosed datalogging system greatly reduces the amount of memory and processing power needed.

A benefit of the disclosed start and stop triggers is that high-speed data may be used during normal tool operations without filling up the data storage on a tool. The cases where errors happen sporadically during normal operation are often the most difficult to replicate and troubleshoot. High-speed datalogging and buffering may be used during normal tool operation to more quickly find a root cause of the errors. Additional data may be collected that is not routinely collected to determine the cause of the issue. The HI module 230 of FIG. 2 may determine the cause of the issue based on previously collected and/or additionally collected data. The HI module 230 may also provide recommendation as to the one or more service operations that may be performed to correct the issue including, for example, maintenance operations, device or component replacement, software updates, system modifications, step-by-step routines to follow, etc. High-speed datalogging and buffering may be performed to capture transitions for each wafer. Using triggers based on digital inputs and outputs and/or analog input thresholds allows for more selective determination of what is logged.

### HI Calculation and Noise Compensation

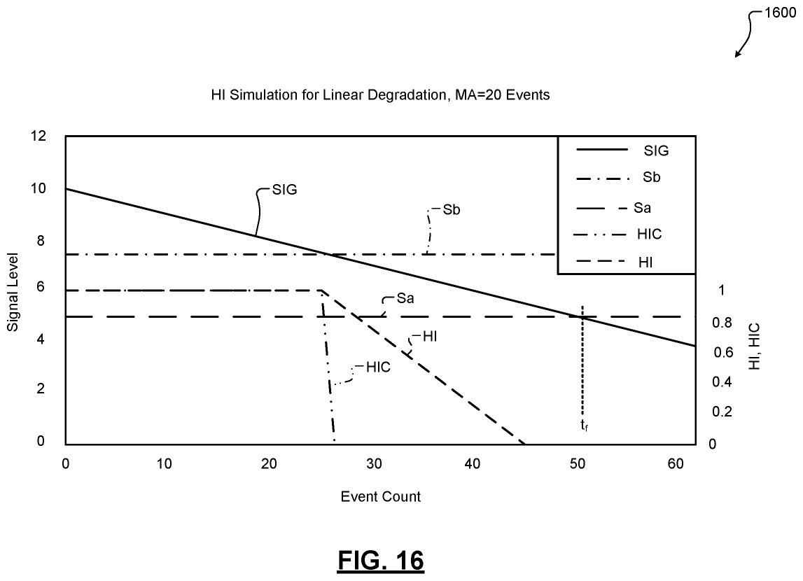

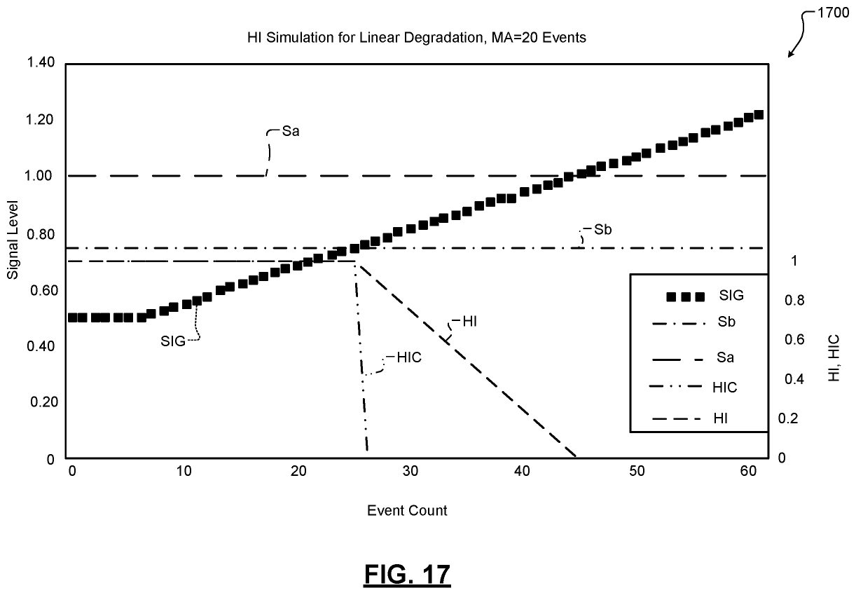

The following operations described with respect to FIGS. 16-21 may be performed by, for example, the health index module 230 of FIG. 2. Health index values are defined and determined such that a lead time is not too short and not too long. The lead time refers to an amount of time between (i) when it is determined that a sensor signal is indicating degradation, and (ii) when an alarm limit for the sensor is reached. The sensor signal will reach an alarm limit in the near future due to the degradation.

FIG. 16 shows an example HI simulation graph 1600 illustrating linear decreasing degradation of a sensor signal SIG from a sensor. The sensor signal SIG may refer to any sensor signal referred to herein. For the same operating condition, the sensor may provide different output values over time due to degradation. This may be due to degradation of the sensor; degradation of calibration of the sensor; degradation of operation of a device, component and/or system being monitored by the sensor; and/or degradation of calibration of a device, component and/or system being monitored by the sensor.

The HI simulation graph 1600 further includes a boundary threshold Sb, an alarm limit Sa, a health index component curve HIC, and a health index curve HI. The boundary threshold Sb provides a threshold, which when crossed by the signal SIG, causes the health index component curve HIC to transition between 0 and 1. A boundary threshold Sb is crossed when a signal SIG equals, drops below, or increases above the boundary threshold Sb. The health index component HIC is a binary value and thus may be either or 1. This is illustrated in FIG. 16 by the health index component curve HIC transitioning from 1 to 0 when the signal line SIG crosses the boundary threshold Sb at approximately an event count of 25. There is a short time delay in transitioning between 1 and 0, which may be as much as two event counts. An event count may refer to seconds, minutes, hours, days, weeks, etc. This transition is shown by segment 1602. For a linear degradation as shown, when the signal SIG crosses the boundary threshold Sb, the health index curve HI decreases from a value of 1 to a value of 0. This rate of decrease in the health index curve HI depends on a predetermined window size, which in the example shown is 20 event counts. An alarm may be generated when the signal SIG crosses the alarm limit Sa, which at this point the device and/or system associated with (e.g., monitored by) the sensor may be shut down (or turned OFF) to, for example, prevent further degradation and/or degradation to other items and/or a substrate being processed.

At least two parameters may be provided as inputs, set and/or predetermined when calculating the health index value. These parameters may include a moving average window MA and the boundary threshold value Sb. The moving average window refers to a number of events over which a binary health index component value may be determined. The health index component curve HIC is a plot of health index component values plotted over time. The health index component values determined over the last predetermined number of event counts may be averaged to provide an updated health index value. Each point of the health index curve HI may be determined in this manner.

The selection of MA and Sb determine (i) the amount of warning time that is given prior to failure and/or the time when the alarm limit Sa is reached by the signal SIG, and (ii) the health index value at failure and/or the time when the alarm limit Sa is reached. In one embodiment, the time of failure is when the signal SIG reaches the alarm limit Sa. In an embodiment, the heath index value decreases to 0 at or prior to the signal SIG reaching the alarm limit Sa. The values MA and Sb may be adjusted to alter how far in advance of the signal SIG reaching the alarm limit Sa that the health index value HI reaches 0.

A simple model is shown in FIG. 16 for when the degradation represented by the signal SIG is linear. In this case, the health index component curve HIC toggles (i.e. transitions) from 1 to 0 as the signal SIG crosses below the boundary level (e.g., Sb=7.5).

In the example shown, this occurs at event count 25. The health index curve HI decreases linearly over the time associated with the moving average window MA. In the example shown, the boundary threshold Sb is set such that the health index curve (or health index value) HI decreases to zero at event count 45, six events prior to the failure even count time of 50.

The boundary threshold Sb may be set such that HI decreases to 0 at about the time when the signal SIG equals Sa. This is referred to as the failure time t_{f}. The failure time t_{f} may be represented by equation (5), where Sₐ=5 in this example, S₀ is the initial or “normal” signal level (S₀ is equal to 10 in this example), and Rₛ is the signal degradation rate in signal units/event count (Rₛ is equal to − 1/10 in this example).

$${t}_{f} = \frac{{S}_{a} - {S}_{0}}{{R}_{s}} \qquad ( 5 )$$

There is a lag time from when HI starts to decrease from 100% (or 1) to when the signal SIG decreases to the boundary threshold Sb, which may be represented by equation 6.

$${t}_{lag} = \frac{{S}_{b} - {S}_{0}}{{R}_{s}} \qquad ( 6 )$$

After substitution and rearranging, equations 7 and 8 hold true.

t_{f}=t_{lag}+MA (7)

S_{b}=Sₐ−Rₛ·MA (8)

The alarm limit Sa may be set based on design requirements and the degradation rate Rₛ is characteristic of the sensor, component, device and/or system being monitored and corresponding operating environment. The value of MA sets the “warning window” in terms of a number of event counts over which HI decreases from 100% to 0%. In one embodiment, the averaging window MA is in time rather than a number of events. In another embodiment, a duration of the averaging window MA is two weeks to provide adequate planning time for a shutdown. During this period of time, a system can be diagnosed to: determine which part(s) need calibration, repair and/or replacing; order and deliver the part(s); schedule a shutdown event to perform the maintenance; and perform any other preparations for the shutdown event.

FIG. 17 shows an example HI simulation graph 1700 illustrating linear increasing degradation of a sensor signal SIG. The signal SIG is shown as a plot of sampled values, as opposed to a continuous curve. Degradation can cause a sensor signal to increase rather than decrease. FIG. 17 shows an increasing example. The HI simulation graph 1700 further includes a boundary threshold Sb, an alarm limit Sa, a health index component curve HIC, and a health index curve HI. In this example, the health index curve HI begins to decrease when the signal SIG crosses the boundary threshold Sb and decreases to 0% when the signal SIG crosses the alarm limit Sa.

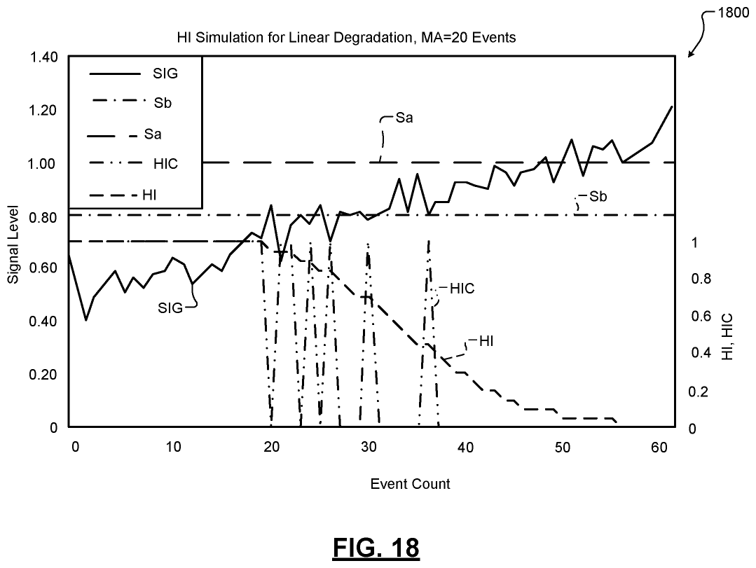

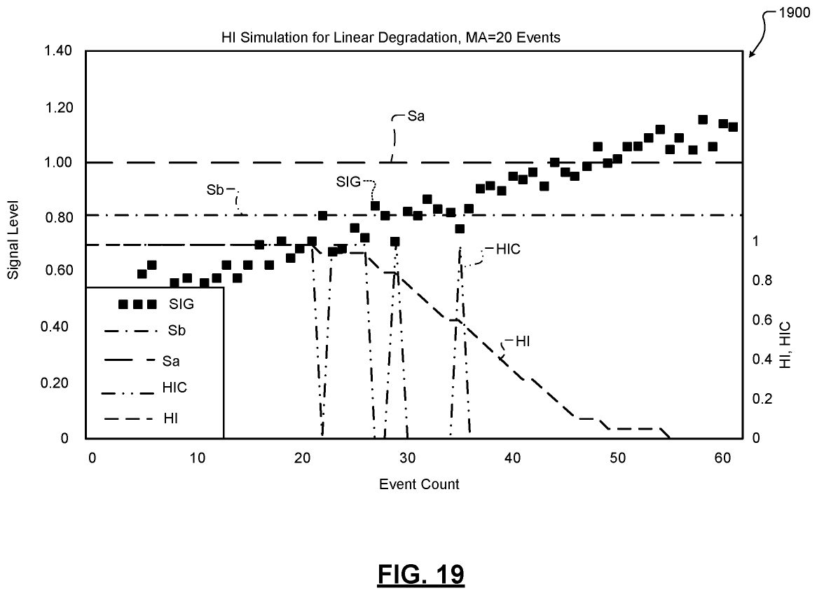

FIG. 18 shows an example HI simulation graph 1800 illustrating linear increasing degradation of a sensor signal SIG with the introduction of noise. The noise causes the signal SIG to no longer be linear, although for the example shown, the signal SIG has an upward linear trend. This is a more realistic representation of a real-world signal.

The HI simulation graph 1800 further includes a boundary threshold Sb, an alarm limit Sa, a health index component curve HIC, and a health index curve HI. The upward trend of the signal SIG linearly rises at + 1/10, starting at approximately 0.5. In the example shown, S_{b}=0.8 and Sₐ=1 and Gaussian noise with a standard deviation σ=0.05 is added. Note that the HIC curve toggles several times between 0 and 1 as the signal SIG crosses the boundary threshold Sb several times. This has the effect of delaying the HI curve from reaching 0 and instead of, for example, the HI curve decreasing at a rate of approximately −0.023 per event count and reaching 0 at approximately the event count 50, the HI curve reaches 0 at the event count 56 as shown. Also note that the alarm level Sa is briefly breeched at t=43 and again at t=47 with respective HI values of approximately 20% and 10%. The crossing at t=43 is due to the noise and could result in a false alarm. However, the HI curve is monitored and since the HIC values are averaged to provide the HI curve, the HI curve does not reach 0 until t=56. As a result, an actual alarm limit may be deemed crossed at t=56. This allows an alarm to be temporarily cleared and production to continue until the HI curve reaches 0. If production was stopped at t=43, then downtime is likely increased and the full useful life of the corresponding parts may not be realized, in other words, cut short.

FIG. 19 shows an example HI simulation graph 1900 including sampled points illustrating linear increasing degradation of a sensor signal SIG with introduction of noise. The sensor signal SIG is show as a plot of sampled points rather than a continuous curve. The HI simulation graph 1900 further includes a boundary threshold Sb, an alarm limit Sa, a health index component curve HIC, and a health index curve HI. As can be seen, the health index component curve HIC toggles between 1 and 0 due to the crossing of the signals SIG over the boundary threshold Sb multiple times. Gaussian noise was added to the signal SIG. The HI zero time is pushed out and the potential for the signal to alarm out prematurely due to the noise component is prevented. The health index curve is robust to noise because of averaging of the health index component curve HIC.

### Adaptive HI Strategy

The degradation rate Rₛ may be estimated. The estimation may depend largely on a noise component in a sensor signal. Taking a derivative of a noisy signal gives a noisier result. For this reason, a smoothing method may be performed. As an example, signal values over a predetermined period of time may be averaged. Consider a time period from an initial time t₀ to a time t₁ after the initial time t₀. During this period, a sensor signal may have degraded from a value SIG₀ to a value SIG₁. An estimate of Rₛ= [symbol] may be represented by equation 9.

$$= \frac{S I {G}_{1} - S I {G}_{0}}{{t}_{1} - {t}_{0}} \qquad ( 9 )$$

Note that [symbol] <0, meaning the degradation rate is always less than 0. Sensitivity can be increased by using a shorter time window. An overestimate of [symbol] may be made to cause the HI value to decrease to zero earlier, and avoid a failure (or sensor signal from reaching an alarm threshold Sa) at HI>0. This aids in assuring that there is time t₀ prepare for the failure. An alternative approach is to curve fit a set of historical sensor signal values in time and calculate a slope along the curve (e.g., at the midpoint or later along the curve). The estimated degradation rate [symbol] may then be determined based on the slope. Although the boundary threshold Sb may be selected based on the degradation rate, small changes in the boundary threshold Sb are made based on the estimated degradation rate [symbol] .

In an embodiment, an objective is to estimate a degradation rate Rₛ of the signal SIG and use the degradation rate Rₛ to alter the boundary level Sb to maintain a warning window MA. There are three potential cases for a HI calculation: (i) a degradation condition where the signal SIG rises towards an alarm condition; (ii) a degradation condition where the signal falls towards the alarm condition; and (iii) a combined case where a two-sided alarm condition exits.

The adaptive HI calculation uses an alarm limit Sa, a boundary threshold Sb, and a moving average window MA. Consider a simple simulation, as shown in FIG. 16, having a simple model where the signal degradation is linear. In this case, the HI component curve (HIC) toggles from 1 to 0 as the signal SIG crosses below the boundary threshold (Sb=7.5), which occurs at event (time) 25. The HI curve decreases linearly over a time window equal to the length of the moving average window MA. In these conditions, a first-in-first-out (FIFO) buffer starts at event 26 to fill with zeros, pushing out the ones from the buffer. The boundary threshold Sb is set in this simulation such that the HI decreases to 0 at event 45, five events prior to the failure time, at event 50. The HIC values are assessed for each measurement. HIC=0 if the signal SIG is between the boundary threshold Sb and the alarm limit Sa, and 1 otherwise.

In an embodiment, the projected failure time is aligned to when HI is close to or equal to 0. Doing so yields equation 10.

S_{b}=Sₐ−Rₛ·MA (10)

Note that the value of Rs is negative here, so that Sb≥Sa. When the alarm limit Sa is above the normal signal level, Rs will be >0 so that Sb will be less than Sa. In this example, there are two set parameters, which are MA and Sb.

In this simple simulation, MA is equal to the “warning window” over which HI transitions for 100% to 0%. In the above simulation the degradation rate was constant and monotonic, but the signal SIG may carry a significant noise component which will cause it to cross over the boundary threshold Sb multiple times for some period of time before fully crossing and moving towards the alarm limit Sa. Thus, the HIC values will not simply step down from 1 to 0, but will toggle for a period of time. The effect on the HI curve is that it gets stretched out in time. If MA is set too long the HI breakdown from 100% may be disregarded or the service operation will be performed too early, potentially sacrificing part service life. In an embodiment, the selection of MA is conservative such that the HI value decreases to 0 prior to or when (i) the signal SIG is fully across the alarm limit Sa, and/or (ii) the trend of the signal SIG reaches the alarm limit Sa.

The MA value may be set at approximately two weeks of operation to provide adequate warning of a failure that would command immediate planning. HI calculations may be performed based on events. When this occurs, an estimate of an expected event rate is made to convert events to calendar time. Alternatively, the MA expressed in events may be allowed to vary while maintaining a constant time window. In an embodiment, a minimum of 20 events is included, as this results in a HI value decrementing at steps of 5% at a time (referred to as age points). In another embodiment, an MA of 50 events is used.

Two example methods for estimating the degradation rate Rₛ are described below. The first method includes a simple moving average window (or warning window). The second method is a kernel technique, which uses a triangular finite impulse response (FIR) filter weighting within a moving window. The second method is more robust to signal noise than the first method.

The simple moving average window method includes estimating the degradation rate Rₛ as a mean step change, ΔSIG over the measurements falling within the warning window MA. For a 20 element span (i.e., MA=20 ΔSIG elements), the degradation rate Rₛ can be estimated using equation 11.

$${R}_{s} = \frac{1}{20} ( {SIG}_{i} - {SIG}_{i - 21} ) \qquad ( 11 )$$

A longer span than MA=20 may be used for noisy signals. The MA value may be variable and have upper and lower bounds.

The triangular FIR filter weighted method includes weighting values within the warning window MA differently, unlike the simple moving average window method, which includes weighting all values within the window equally. In the triangular weighted method, the weights are normalized to sum up to 1. For an 8-element window the weights are [1,2,3,4,4,3,2,1] with sum=20, so the first weight is 1/20, the second 2/20, etc. For a 10-element window the weights are [1,2,3,4,5,5,4,3,2,1] with sum=30. Thus in general the estimate for Rₛ may be represented by equation 12, where ΔSIGᵢ=SIG₀−SIG₁.

Rₛ=Σᵢ₌₁ⁿwᵢΔSIGᵢ (12)

Thus, the n most recent ΔSIG values are buffered and then the weighted summation is calculated. If the window length is varied, multiple sets of weights are stored. In one embodiment and to prevent the degradation rate from “backtracking”, the degradation rate is Rₛ[i] if |Rₛ[i]|≥|Rₛ[i−1]|.

Two-sided alarm limits may be used when the signal SIG is able to degrade in either direction (increasing or decreasing directions) such that the degradation rate reverses. There are four possible cases, but if |Rₛ[i]|≤|Rₛ[i−1]|, the degradation has “backed off,” and Rₛ[i−1] is retained. The other two cases are deemed “strong” changes which are honored (stored and used) regardless of direction.

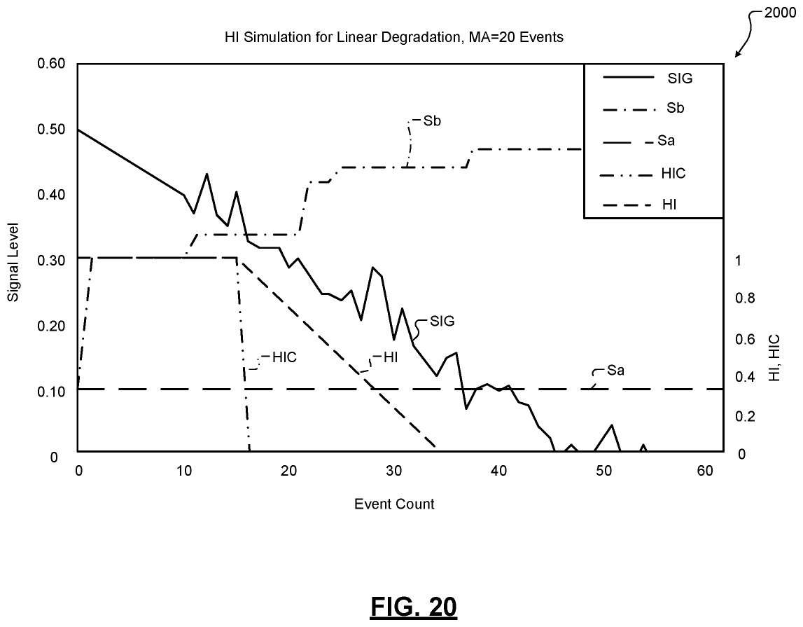

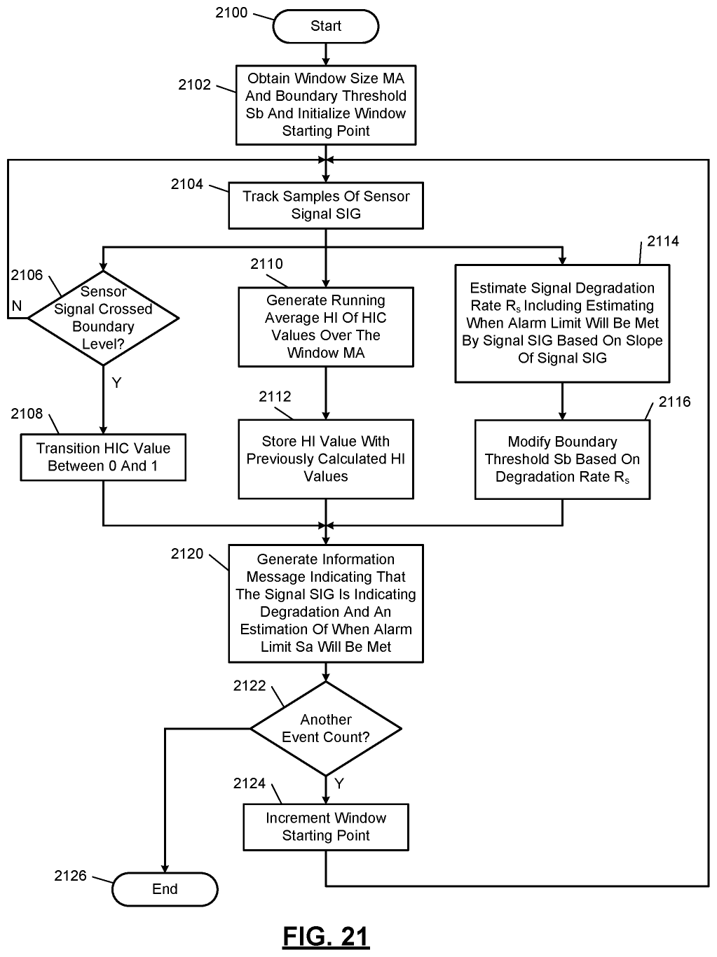

FIG. 20 shows a HI simulation graph 2000 illustrating linear decreasing degradation of a sensor signal SIG with introduction of noise and an adaptive boundary threshold Sb. As can be seen, the adaptive boundary threshold Sb is not a fixed parameter, but rather varies and is based on the alarm limit Sa, the degradation rate Rₛ and the moving average window MA. The threshold Sb may be determined using above equation 10. The graph 2000 includes the alarm limit Sa, a health index component curve HIC, and a health index curve HI.

The boundary threshold Sb is adjusted over time such that the health index curve HI decreases to 0 prior to or when the signal SIG reaches the alarm limit Sa. In an embodiment, the adaptive algorithm varies the boundary threshold Sb over time by iteratively determining the slope of the signal SIG and projecting it to where the signal SIG is going to cross the alarm limit Sa. The boundary threshold Sb is then adjusted based on this projection.

FIG. 21 shows an example process for obtaining HI values, which includes the triangular FIR filter weighted method. The process and/or portions thereof may be iteratively performed. The process may begin at 2100. At 2102, the health index module 230 of FIG. 2 determines, sets, selects and/or obtains a moving average (or warning) window size MA and an initial boundary threshold Sb. The health index module 230 may, for example, set a time for the window MA to be equal to approximately two week ±1-2 days. This may include setting the window MA, or the number of event counts, based upon an event count frequency. The MA may be a user settable parameter. The health index module 230 also sets an initial starting point for the window MA.

At 2104, the health index module 230 tracks samples (n) of a sensor signal SIG. The health index module 230 may retain the prior n measurements of ΔSIG spread out along the time span of MA, where n is an integer greater than 1.

The following operations 2106, 2108 may be performed in parallel with operations 2110, 2112 and in parallel with operations 2114, 2116.

At 2106, the health index module 230 determines whether the sensor signal SIG has crossed the boundary threshold Sb. If yes, operation 2108 may be performed, otherwise operation 2104 may be performed. At 2108, the health index module 230 transitions the HIC value between 0 and 1.

At 2110, the health index module 230 generates a running average HI value of health index component (HIC) values over a time frame of the window. The health index module 230 may calculate the running average HI value as a moving average of event classification values (referring to the HIC values) stored in a FIFO buffer against the last determined threshold boundary Sb.

At 2112, the health index module 230 stores the running average HI value with previously calculated running average HI values. As an example, 30 days of running average HI values may be stored for future evaluation.

At 2114, the health index module 230 estimates signal degradation rate Rₛ. This may be accomplished using above equation 10 and may include estimating when the alarm limit will be met by the signal SIG based on the slope of the signal SIG. the health index module 230 estimates Rₛ as a weighted summation of the most recent n values of ΔSIG. At 2116, the health index module 230 modifies the boundary threshold Sb based on the estimated signal degradation rate Rₛ, as described above.

At 2120, the health index module 230 generates an information message, as a countermeasure, indicating that the signal SIG indicates degradation and an estimation of when an alarm limit Sa will be met by the signal SIG. This may include generating a soft alarm to a user warning the user that an alarm limit will be met in the near future and to schedule a shutdown event for maintenance. This allows actions to be taken to minimize the duration of the future shutdown event.

At 2122, the health index module 230 determines whether there is another event count. If yes, operation 2124 is performed, otherwise the method may end at 2126. At 2124, the health index module 230 increments the window starting point.

The above-described operations of the methods and processes disclosed herein are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

As another example, health index monitoring may be performed as described above and applied to sensors used to detect substrate slippage on an end effector. Digital/analog sensor data from these sensors may be used to detect slippage using a health index algorithm, method and/or process disclosed herein. This may be done to prevent damage to a substrate. The sensors may be used to detect placement of the substrate on the end effector at different location along a path over which the substrate is moved. A substrate may be moved by the end effector between different chambers and/or air-locks. The relative placement (or position) of a center of the substrate relative to an intended position for the center of the substrate relative to an end effector may be determined. This determination may be made, for example, each time the substrate is entering and/or leaving an air-lock and/or chamber (e.g., a processing chamber). The difference in the stated positions and the change in this difference, when moved from location to location indicates slippage and whether the amount of slippage is changing. A difference greater than zero can indicate that the substrate has slipped and/or not in a correct position relative to the end effector. Health index monitoring may be used to determining whether maintenance of the sensors, the end effector, and/or another component(s) and/or device(s) will need maintenance.

The foregoing description is merely illustrative in nature and is in no way intended to limit the disclosure, its application, or uses. The broad teachings of the disclosure can be implemented in a variety of forms. Therefore, while this disclosure includes particular embodiments, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described embodiments. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. In some embodiments, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some embodiments, a remote computer (e.g. a server) can provide process recipes to a system over a network, which may include a local network or the Internet. The remote computer may include a user interface that enables entry or programming of parameters and/or settings, which are then communicated to the system from the remote computer. In some embodiments, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A health monitoring, assessing and response system comprising:
an interface configured to receive a first signal from a first sensor disposed in a substrate processing system; and
a controller comprising a health index module, wherein
the health index module is configured to perform an algorithm comprising
obtaining a window and a boundary threshold,
monitoring the first signal output from the first sensor,
determining whether the first signal has crossed the boundary threshold,
updating a health index component, wherein the health index component is a binary value and transitioned between HIGH and LOW values in response to the first signal crossing the boundary threshold, and
generating a first health index value based on the health index component and decreasing the first health index value from 100% to 0% over a duration of at least the window, and
the controller is configured to perform a countermeasure based on the first health index value.

2. The health monitoring, assessing and response system of claim 1, wherein:
the health index module is configured to generate the first health index value as an average of updated values of the health index component over a duration of the window; and
the updated values of the health index component are determined during respective iterations of the algorithm.

3. The health monitoring, assessing and response system of claim 1, wherein:
the health index module is configured to generate an updated health index value during each iteration of the algorithm; and
the controller is configured to perform the countermeasure based on the updated health index values.

4. The health monitoring, assessing and response system of claim 1, wherein the health index module is configured to select the window and the boundary threshold such that the health index value decreases to 0% prior to or when the first signal reaches an alarm limit.

5. The health monitoring, assessing and response system of claim 1, wherein the health index module is configured to adaptively adjust the boundary threshold during iterations of the algorithm to extend an amount of time during which the health index value decreases from 100% to 0%.

6. The health monitoring, assessing and response system of claim 1, wherein the health index module is configured to adaptively adjust the boundary threshold during iterations of the algorithm such that the health index value decreases to 0% prior to or when the first signal equals an alarm limit.

7. The health monitoring, assessing and response system of claim 1, wherein the health index module is configured to:
implement a finite impulse response filter to determine a degradation rate of the first signal; and
adjust the boundary threshold based on the degradation rate.

8. The health monitoring, assessing and response system of claim 1, wherein the health index module is configured to determine the boundary threshold based on a degradation rate of the first signal, a duration of the window, and an alarm limit.

9. The health monitoring, assessing and response system of claim 1, wherein the health index module is configured to:
estimate a degradation rate of the first signal as a sum of weighted changes in the first signal; and
determine the boundary threshold based on the estimated degradation rate.

10. The health monitoring, assessing and response system of claim 1, wherein the controller is configured to perform the countermeasure in response to at least one of the first health index value decreasing, reaching a predetermined level or being within a predetermined range.

11. The health monitoring, assessing and response system of claim 1, wherein:
the interface is configured to receive N signals from N sensors disposed in the substrate processing system, where N is greater than or equal to two, wherein the N signals include the first signal, and wherein the N sensors include the first sensor;
the health index module is configured to
monitor the N signals output respectively from the N sensors,
assess the N signals to determine a plurality of health index values including the first health index value, and
aggregate the plurality of health index values to determine a system health index value; and
the controller is configured to perform the countermeasure in response to at least one of the system health index value decreasing, reaching a predetermined level or being within a predetermined range.

12. A health monitoring, assessing and response system comprising:
an interface configured to receive data from N sensors disposed in a substrate processing system, where N is greater than or equal to two; and
a controller comprising a health index module, wherein
the health index module is configured to
receive sets of data output respectively from the N sensors,
assess the sets of received data to determine a plurality of health index values, and
aggregate the plurality of health index values to determine a system health index value, and
the controller is configured to perform a countermeasure in response to at least one of the system health index value decreasing, reaching a predetermined level or being within a predetermined range.

13. The health monitoring, assessing and response system of claim 12, wherein the health index module is configured to:
determine second order polynomials respectively for the sets of data received from the N sensors; and
determine the one or more health index values based on coefficients of the determined second order polynomials.

14. The health monitoring, assessing and response system of claim 13, wherein the health index module is configured to:
compare the coefficients to a statistical distribution; and
determine the plurality of health index values based on results of the comparison of the coefficients to the statistical distribution.

15. The health monitoring, assessing and response system of claim 13, wherein the health index module is configured to:
determine distributions of the coefficients;
compare the distributions to health index boundaries; and
determine the one or more health index values based on results of comparing the distributions to the health index boundaries.

16. The health monitoring, assessing and response system of claim 12, wherein the health index module is configured to determine the system health index value based on a hierarchical structuring of health index calculations corresponding to at least one of a physical or functional decomposition of the substrate processing system.

17. The health monitoring, assessing and response system of claim 12, wherein the health index module is configured to implement an aggregation algorithm and use Boolean operations corresponding to redundancy or lack of redundancy when determining the plurality of health index values and the system health index value.

18. The health monitoring, assessing and response system of claim 12, wherein the health index module is configured to select a minimum health index value of at least one of a hierarchical level or a sub-system level of the substrate processing system when generating the system health index value.

19. The health monitoring, assessing and response system of claim 12, wherein each of the plurality of health index values and the system health index value is between 0-100%.

20. The health monitoring, assessing and response system of claim 12, wherein the controller is configured to define an event of the substrate processing system, indicated based on the system health index value as being abnormal, but within an acceptable range such that the controller refrains from generating an alarm or stopping operation of the substrate processing system.

21. The health monitoring, assessing and response system of claim 12, wherein the health index module is configured to generate the plurality of health index values based on N respective sets of events of the substrate processing system as detected by the N sensors.

22. The health monitoring, assessing and response system of claim 21, wherein the health index module is configured to generate the plurality of health index values based on whether the N respective sets of events fall within defined normal operating conditions.

23. The health monitoring, assessing and response system of claim 12, wherein the health index module is configured to:
use acquired data from an analog sensor over a time period defined by determined states of the substrate processing system;
use a mathematical model to compute a secondary value characteristic of substrate processing system operation during the time period; and
generate the system health index value based on the secondary value.

24. The health monitoring, assessing and response system of claim 12, wherein the health index module is configured to scale the system health index value between a defined boundary level and an alarm level to indicate a severity of an operating condition beyond the defined boundary level.

25. The health monitoring, assessing and response system of claim 24, wherein the health index module uses non-linear scaling.

26. The health monitoring, assessing and response system of claim 12, wherein the controller comprises a sensor mapping module configured to display at least one portion of the substrate processing system and information associated with the N sensors.

27. The health monitoring, assessing and response system of claim 26, wherein the sensor mapping module is configured to display sensor identifiers, sensor states, and the plurality of health index values over the at least one portion of the substrate processing system.

28. The health monitoring, assessing and response system of claim 26, wherein the sensor mapping module is configured to display the plurality of health index values in a hierarchical format.

29. The health monitoring, assessing and response system of claim 26, wherein the sensor mapping module is configured to indicate physical locations of the N sensors in the substrate processing system.

30. The health monitoring, assessing and response system of claim 26, wherein the sensor mapping module is configured to selectively, based on at least a received instruction, display one or more of the plurality of health index values for a selected hierarchical level of the substrate processing system.

31. The health monitoring, assessing and response system of claim 26, wherein the sensor mapping module is configured to display historical health index values for the N sensors.

32. The health monitoring, assessing and response system of claim 26, wherein the sensor mapping module is configured to, based on a received instruction, display an aggregation level of health index values.

33. The health monitoring, assessing and response system of claim 12, wherein the health index module is configured to:
determine normal operating boundaries based on operating the substrate processing system in a normal state for a selected period of time; and
detect a potential issue or fault based on the normal operating boundaries.

34. The health monitoring, assessing and response system of claim 12, wherein the health index module is configured to use time intervals between defined operations of the substrate processing system as a basis for determining the plurality of health index values.

35. The health monitoring, assessing and response system of claim 12, wherein the health index module is configured to use a mathematical module based on conditions to reduce the received data to a set of values based on which of the plurality of health index values are calculated.

36. The health monitoring, assessing and response system of claim 12, wherein the health index module is configured to determine the plurality of health index values periodically and based on one or more detected events of the substrate processing system as detected by the N sensors.

37. The health monitoring, assessing and response system of claim 12, wherein the health index module is configured to determine the plurality of health index values based on a degree to which operation of the substrate processing system approaches an alarm limit.

38. The health monitoring, assessing and response system of claim 12, wherein:
the health index module is configured to determine the plurality of health index values based on respective parameter distribution boundaries; and
each of the parameter distribution boundaries are located between a normal operation range and an alarm limit for a corresponding parameter.

39. The health monitoring, assessing and response system of claim 12, wherein the controller comprises a datalogging module, wherein the datalogging module is configured to collect and store data from the N sensors.

40. The health monitoring, assessing and response system of claim 39, wherein the datalogging module is configured to, based on at least one of the plurality of health index values or rates of change of output values of the N sensors, initiate data collection from the N sensors or a subset of the N sensors.

41. The health monitoring, assessing and response system of claim 39, wherein the datalogging module is configured to, based on at least one of the plurality of health index values or rates of change of output values of the N sensors, increase a data sampling rate and collect data from the N sensors or a subset of the N sensors at the increased data rate.

42. The health monitoring, assessing and response system of claim 12, wherein the health index module is configured to:
detect degradation in the substrate processing system based on the system health index value; and
collect additional data to determine a cause of the detected degradation.

43. The health monitoring, assessing and response system of claim 12, further comprising the N sensors.

44. A sensor mapping system comprising:
N sensors configured to detect respective parameters of a substrate processing system, where N is greater than or equal to two;
an interface configured to receive data from the N sensors; and
a controller comprising a sensor mapping module, wherein the sensor mapping module is configured to
receive instructions to display sensor information for the N sensors,
receive data output respectively from the N sensors, and
display locations of the N sensors along with the sensor information over a view of at least a portion of the substrate processing system.

45. The sensor mapping system of claim 44, wherein the sensor information comprises at least one of a current sensor value, a historical aggregate value, a health index value, a part number, or a serial number.

46. The sensor mapping system of claim 44, wherein the sensor mapping module is configured to display a state of at least one of the N sensors over the view of the at least a portion of the substrate processing system.

47. The sensor mapping system of claim 44, wherein:
the controller further comprises a health index module configured to generate a plurality of health index values respectively for the N sensors; and
the sensor mapping module is configured to display the plurality of health index values over the view of the at least a portion of the substrate processing system.

48. The sensor mapping system of claim 47, wherein the sensor mapping module is configured to receive instructions from the health index module, wherein the instructions include selection of the N sensors from a set of M sensors, where M is greater than N.

49. The sensor mapping system of claim 44, wherein the sensor mapping module is configured to:
receive an instruction signal; and
based on the instruction signal, plot data received from one or more of the N sensors.

50. The sensor mapping system of claim 44, wherein the sensor mapping module is configured to:
receive an input to display a plot of data for one of the N sensors; and
display a graph including plotting data from the one of the N sensors, wherein the graph is shown on a same screen as the view of the at least the portion of the substrate processing system.

51. The sensor mapping system of claim 44, wherein the sensor mapping module is configured to, based on a received input, change at least one of a screen level or a displayed hierarchical level of the substrate processing system.

52. The sensor mapping system of claim 44, wherein the sensor mapping module is configured to, based on an input, display sensor information for M sensors of the substrate processing system rather than the sensor information for the N sensors, where M is greater than or equal to 2.

53. The sensor mapping system of claim 52, wherein the M sensors are exclusive of the N sensors.

54. The sensor mapping system of claim 52, wherein the M sensors include one or more of the N sensors.

55. A datalogging system comprising:
N sensors configured to detect respective parameters of a substrate processing system, where N is greater than or equal to two;
an interface configured to receive data from the N sensors; and
a controller comprising a datalogging module, wherein the datalogging module is configured to
receive instructions to select one or more of the N sensors and trigger information,
monitor at least one of the N sensors and detect one or more trigger events identified by the trigger information, and
data log outputs of the selected one or more of the N sensors in response to detecting the one or more trigger events to provide logged data,
wherein the controller is configured to analyze the logged data and based on result of analyzing the logged data, performing a countermeasure.

56. The datalogging system of claim 55, wherein the datalogging module is configured to:
receive instructions from a health index module, wherein the instructions include a selected set of sensors and triggers; and
based on the triggers, log data from the selected set of sensors.

57. The datalogging system of claim 56, wherein the selected set of sensors does not include the N sensors.

58. The datalogging system of claim 55, wherein:
the datalogging module is configured to perform datalogging based on at least one of triggers, thresholds or conditions; and
the controller comprises a health index module configured to
classify whether one or more operations of the substrate processing system occurred inside or outside of defined normal operating conditions,
generate a plurality of health index values based on the classified one or more operations, and
perform the countermeasure based on an aggregation of the plurality of health index values.

59. The datalogging system of claim 55, wherein the datalogging module is configured to:
buffer data prior to the one or more trigger events; and
store data for a set time period prior to the one or more trigger events.

60. The datalogging system of claim 55, wherein the datalogging module is configured to log data for the N sensors based on trigger events associated with one or more other sensors.

61. The datalogging system of claim 55, wherein the datalogging module is configured to log data for the N sensors based on a detected one or more conditions of the substrate processing system.

62. The datalogging system of claim 55, wherein the datalogging module is configured to capture intermittent events by recording data output from the N sensors for a set time period each time a triggering event occurs.
